(19) United States
(12) Patent Application Publication
(10) Pub. No.: US 2011/0192460 A1
(43) Pub. Date: Aug. 11, 2011

(54) Solar Power Generator

(76) Inventor: Raymond Tan, Toronto (CA)

(21) Appl. No.: 12/702,561

(22) Filed: Feb. 9, 2010

(51) Int. Cl. H01L 31/00

(52) U.S. Cl. 136/257

(57) ABSTRACT

Renewable energy sources provide electricity without consuming fossil fuels and contributing to emissions that impact the global environment. Unlike wind and water methods solar photovoltaic generators provide this renewable energy without geographic or meteorological limitations. However, today electricity generation from solar using photovoltaics is more expensive than fossil fuel sources and is generally limited to deployments with large planar photovoltaic panels. According to embodiments of the invention concentrator based azimuth-altitude tracking solar power generators are provided offering reduced electricity generation costs, reduced installation costs, increased flexibility in deployment and locations of deployment, and initial system costs. The optical assembly comprises a concentrating lens and a reflector to couple the solar radiation to the photovoltaic cell. The concentrating lens is offset out of the plane parallel to the photovoltaic cell whilst the reflector and the reflector may be disposed angularly offset to an axis perpendicular to the photovoltaic cell.

### FIELD OF THE INVENTION

This invention relates to solar energy and more specifically to an optical configuration for increasing output power.

### BACKGROUND OF THE INVENTION

Interest in photovoltaic cells has grown rapidly in the past few decades, such photovoltaic cells comprising semiconductor junctions such as p-n junctions. It is well known that light with photon energy greater than the band gap of an absorbing semiconductor layer in a semiconductor junction is absorbed by the layer. Such absorption causes optical excitation and the release of free electrons and free holes in the semiconductor. Because of the potential difference that exists at a semiconductor junction (e.g., a p-n junction), these released holes and electrons move across the junction in opposite directions and thereby give rise to flow of an electric current that is capable of delivering power to an external circuit. As such photovoltaic cells offer a source of renewable energy as once installed all they require is the sun to generate electricity.

Referring to FIG. 1 there is shown global map 100 that depicts the average annual ground solar energy over the period 1983-2005 (from http://www.parario.com/resources/economy/articles/1/article.html) that shows for most of South America, Africa, India, South East Asia, and Australia that solar energy is between approximately 6.5 kWh/m²/day→7.5 kWh/m²/day. Within North America, Europe, Russia and northern China the solar energy drops to approximately 4.5 kWh/m²/day→6 kWh/m²/day. Overall as shown in table 150 in FIG. 1 the total solar energy received is approximately 85,000 TW compared to an annual global energy consumption of 15 TW. Importantly this solar energy is renewable unlike the dominant energy sources providing the current global consumption of 15 TW. As shown in table 250 in FIG. 2 current energy consumption is provided predominantly, approximately 87%, by fossil fuels where in the period 1984-2006 despite multiple global oil crises arising from war, political instability, financial markets etc and the increased global focus to so-called “green” activities such as recycling, renewable energy, energy conservation etc the dependence on fossil fuels has dropped only ˜4% despite overall energy consumption increasing approximately 167%. The majority of this reduction, approximately 3.3% of the 4% comes actually from the increase in nuclear energy production globally.

At present renewable energy sources account for approximately 1% of global energy production and penetration has been limited to very few commercial applications. Within the United States solar photovoltaic (PV) energy production accounted for approximately 0.1% of energy production despite as evident from continental US map 200 that solar radiation across a significant portion of the continental United States receives 6.5 kWh/m²/day→7.5 kWh/m²/day. This being particularly so in the south western states of California, Arizona, New Mexico, Texas, Colorado, Nevada, and Utah representing approximately 25% of the US population, where incentives for renewable energy and protecting the environment are strong, and where conditions annually do not vary significantly unlike the north eastern states. So what is preventing the wider penetration of PV energy sources when Government incentives such as San Francisco's Public Utilities Commission GoSolarSF program in conjunction with the State of California pays at least 50% of the cost of a solar power system. Incentives within the United States vary state to state (see for example Database for State Incentives for Renewable & Efficiency, http://www.dsireusa.org/summarytables/finre.cfm) but include personal, corporate, sales and property tax deductions, rebates, grants, loans as well as industry support, bonds and production incentives.

Referring to cost graph 275 in FIG. 2 there is presented the projected energy generation cost of electricity for four different PV solar cell technologies with time, these being crystalline silicon 255 (c-Si), amorphous silicon 260 (α-Si), copper indium gallium diselenide 265 (CuInGaSe₂, commonly referred to as CIGS) and cadmium telluride 270 (CdTe) respectively. As is evident all four technologies trend over the projected period of 2006-2020 from 24-30 cents per kWh (0.24$/kWh to 0.30$/kWh) to between 8-10 cents per kWh (0.08$/kWh to 0.10$/kWh). In 2006 average electricity cost in the continental US was (see Stephen O'Rourke, Deutsche Bank Securities at http://newsletters.pennnet.com/semiweekly/10183121.html) was 8.6 cents per kWh (0.086$/kWh). Also shown in cost graph 275 is a family of curves 285 which project electrical costs from conventional fossil fuel sources are shown for four annual inflation rates of 4% to 7%. Hence according to these projections no convergence of solar PV costs as being comparable to fossil fuel production is expected until the time period 2013 to 2016, convergence 280, despite the significant effort and capital expenditure being invested into PV cell technologies and solar cell manufacturing technologies. This convergence sliding out in time if inflation stays low.

Amongst the aspects of PV cells for electrical power generation is their efficiency. Referring to FIG. 3 there is shown graph 300 of PV cell efficiency versus time from 1975 to today. Considering first the four technologies plotted in cost graph 275 of FIG. 2 then there is shown α-Si 315 where best reported efficiencies have remained quite stable at around 12%, CdTe 325 where reported efficiencies are approximately 16.5%, CIGS 320 which has peaked at approximately 20% and c-Si 335 where efficiencies are approximately 25%. Due to its similarity with other silicon PV technologies and the massive existing silicon manufacturing infrastructure multicrystalline Si 330 has also been subject of significant research demonstrating comparable efficiencies around 20% as CIGS. Significant research and development has gone into other semiconductor materials such as gallium arsenide 340 (GaAs) at approximately 28% and multi-junction indium gallium arsenide phosphide 345 (InGaAsP) where developments continue to present improvements having reached approximately 40% efficiency as of the end of 2009. GaAs 340 and InGaAsP 345 seek to exploit the broader wavelength range of solar radiation than is accessible with silicon and potentially offer a path to significantly higher efficiencies by the introduction of quantum well, quantum dot and nanowire technologies. However, their increased efficiency comes at a cost as their manufacturing processes are more expensive and largest commercial wafers being 100 mm (4 inch) whereas silicon commercial wafers are typically 200 mm (8 inch) and 300 mm (10 inch) today.

Also shown are organic cells 305 and dye sensitized cells 310, the later employing a porous film of nanocrystalline titanium dioxide (TiO2) particles deposited onto a conducting glass electrode with organic dyes to provide visible sensitivity for conduction effects in the TiO2 which otherwise is limited to ultraviolet wavelengths. Each of these technologies promising the ability to fabricate low cost large area PV cells but at present despite significant research, for example over 800 patents on dye sensitized cells 310 alone, their efficiencies at approximately 5% and 10% respectively still require large solar panels to generate any significant power.

Accordingly, the erosion in electricity cost outlined in cost graph 275 is projected by analysts to occur not from fundamental PV materials technology but from a combination of increased efficiencies in manufacturing arising from increased wafer dimensions, i.e. moving from 200 mm production to 300 mm production, and the reduced cost of raw materials. A dominant raw material cost being the silicon wafers upon which the PV cells are fabricated. Referring to wafer cost 450 in FIG. 4 the silicon consumption 460 is plotted according to data from the US National Solar Technology Roadmap published by the US Department of Energy showing a reduction from 12 g/Wp (grammes per Watt peak) to 7.5 g/Wp over the period 2004-2010 and being achieved through the reduction in wafer thickness 455 from 300 μm to 150 μm. The projected wafer thickness 465 in 2015 being 2015 at which point as shown in solar panel cost graph 400 in FIG. 4 the US National Solar Technology Roadmap target solar panel cost is $1/W. As shown by US cost curve 410 current pricing has not substantially eroded over the period 2001-2009 dropping from ˜$5.50/W to $4.25/W. European cost curve 420 showing a similar trend.

Accordingly, focus has historically been placed within the prior art on PV cell materials such as discussed supra and methods of assembling the multiple low efficiency solar cells into solar panels such as are familiar to consumers such as depicted in FIG. 5 by panels 540. At present PV cells is characterized by several niches within the following applications:
Building Integrated Photovoltaics (BIPV), such as shown by residential deployment 510 wherein PV panel arrays are mounted on building roofs and facades. This market segment includes hybrid power systems, combining diesel generators, batteries and PV generation capacity for off-grid remote cabins;
Non-BIPV Electricity Generation (both grid interactive and remote), and includes for example solar farms 530 such as First Light Solar Park in Canada employing over 126,000 solar panels spanning across 90 acres to provide approximately 1 MW of electricity and the New Deming, N. Mex., USA solar farm producing 300 MW. This market includes distributed generation (e.g., stand-alone PV systems or hybrid systems including diesel generators, battery storage and other renewable technologies), water pumping and power for irrigation, and power for cathodic protection;
Communications, such as shown by pole mounted PV panel 520 wherein PV systems provide power for remote telecommunications repeaters, fiber optic amplifiers, rural telephones and highway call boxes. Such PV modules also provide power for remote data acquisition for both land-based and offshore operations including the oil and gas industry;
Transportation, where examples include power for boats, cars, recreational vehicles etc as well as for transportation support and management systems such as message boards, warning signals on streets and highways, as well as monitoring cameras, data acquisition etc; and
Consumer Electronics, where examples include landscaping lighting, battery chargers, etc.

These deployments of solar panels typically employ simple geometries wherein the solar panel is flat and fixed into a predetermined orientation despite the fact that the elevation and orientation of the sun relative to the solar panels changes not only daily but seasonally. As such the actual efficiency of such solar panel deployments only reaches the stated values for the assembled units for a small portion of the actual operation since this is achieved when the plane PV cells are perpendicular to the axis of the sun to the surface at that point. This daily variation for planar PV panels is shown by power graph 550 in FIG. 5.

It would also be apparent that current commercial developments such as driven by the National Solar Technology program under the US Department of Energy for PV cells and panels are focused to the cost reduction of the semiconductor photovoltaic cells and wafers together with their encapsulation, interconnection, etc. However, it would be apparent that increasing the area of the PV cells whilst increasing the electrical power of the solar assembly does so with a cost that is approximately linear to the output, as this is essentially linear with area of the PV cells, silicon used, packaging materials, assembly etc. Accordingly it would be beneficial to provide an increase in electrical power output for a given area of PV cell, and thereby lower costs both in the near-term but also importantly once large-volume production of any of the identified PV cell technologies identified in FIG. 3 is reached. Once such approach is so-called concentrating photovoltaic (CPV) which due to immediate and long-term benefits has inspired substantial venture capital investment in CPV in recent years. The concentrator developments leverage work done for PV cells and concentrating thermal technologies for providing heating to buildings or generating electricity through turbines driven by heated liquid/gas systems. However, challenges for these CPV approaches include additional complexity, a much smaller market presence, and a very limited history of reliability/field-test data.

Estimates by bodies such as the Arizona Public Service based upon developments such as the Amonix High Concentration PV system (see for example http://www.aps.com/_files/renewable/RT003AmonixHCPVTechnology.pdf and http://www.aps.com/my_community/Solar/Solar_{—}15.html) have projected that CPV systems will overtake tracked flat-plate PV as the most cost-effective PV for commercial/utility-scale applications, with costs coming down to 0.06$/kWh. Potentially such systems may accelerate cost erosion and bring forward the convergence 280 in FIG. 2 with some predictions advancing this to 2011. Important the cost effectiveness additionally benefits from the economies of scale as manufacturing developments, such as outlined supra in respect of FIG. 4, and advanced high-efficiency PV technologies, such as outlined supra in respect of FIG. 3, are incorporated. However, to date, the total installed CPV capacity is <1 MW in the United States and only a few MW worldwide, virtually all using silicon PV cells. Thus, the fundamental challenge of CPV is to lower cost, increase efficiency, and demonstrate reliability to overcome the barriers to entry into the market at a large scale. These challenges must all be addressed at the system level and include:
System-Level Design, where PV cell, optical train, and tracking must be engineered not only to work together but need to be designed for manufacturability, as well as cost, with attention given to tolerance chains, automation, scalability, and ease of assembly, maintenance;
Reliability, where factors specific to conventional prior art CPV systems include the high-flux, high-current, high-temperature operating environment encountered by the cells; weathering and other degradation of the optical elements, the mechanical stability of the optical train, and the operation of the mechanical parts of the tracking systems;
Cost, where PV cell cost is a substantial fraction of the total system cost, currently a reasonable estimate for a concentration system operating at 500× would be between 30% and 50% and as discussed supra reduction methodologies are well documented using silicon PV technologies but further reduction may be achieved by combining these with increased solar concentration and reduced costs for the mechanical and thermal aspects of the solar power generator. Such approaches to lowering the cost of the system include system design for reducing required tracking accuracy, as well as refined mechanical engineering of the tracker, designing optical trains that are compatible with techniques for inexpensive, robust fabrication of what may in some designs be sophisticated optical surfaces, and provision of low cost thermal management solutions; and
Efficiency, as improved efficiency is a direct way to lower the cost of the system and the area required to host a system for given power output; the area can have a significant effect on cost of electricity in most systems. As with cost and reliability, efficiency must be addressed at the system level to reduce parasitic losses so that systems can realize their potential efficiencies.

Considering firstly the tracking system a variety of prior art techniques have been reported including polar, horizontal axle, vertical axle, two-axis altitude-azimuth, and multi-mirror reflective altitude-azimuth. For planar PV cells single axis tracking increases annual output by approximately 30% whilst adding the second axis adds approximately a further 6%. As such only single axis tracking is typically employed with such cells. However CPV systems typically position the PV cell at the focal point of the optical train such that the increased complexity of two axis or altitude-azimuth tracking is required. Control of the tracking is generally dynamic, i.e. monitoring the solar signal within the optical train, passive by exploiting solar energy, or so-called chronological tracking wherein control is preprogrammed day-time variations.

An example of a tracking system according to the prior art of T. Green in US Patent Application 2009/0,272,425 entitled “Concentrating Solar Energy Receiver” is shown in FIG. 6 with solar generator 600. This comprises a solar reflector 610 is mounted upon an altitude-azimuth tracking mount 605. Solar radiation from the solar reflector is reflected and concentrated to a second annular reflector 620 wherein it is reflected to the concentration region 625. Solar radiation within the central region of the solar reflector 610 in contrast is focused by lens 615 into the concentration region 625. Mounted below concentration region is electricity generator 605B that converts the thermal energy within the concentration region to electricity. Green further teaches that the lens 625 is manufactured from multiple elements, being first element 635 of an ultraviolet compatible acrylic, second element 640 of polycarbonate and third element 645 of an infrared polycarbonate. The use of plastics being taught to reduce weight due to the large physical dimensions of the lens which essentially has the same dimensions as electricity generator 605B. Multiple plastics being taught to increase the solar energy collected by extending operation into the infrared and ultraviolet. Extension of this technique into PV cells requires that multiple PV cells be employed, each optimized to particular wavelength ranges such that the concentrator also provides wavelength separation to couple to these multiple cells. Such an approach being reported by J. P Penn in U.S. Pat. No. 6,469,241 entitled “High Concentration Spectrum Splitting Solar Collector”.

The selection of control and tracking mechanism is also determined in dependence of the concentration. For example so-called low concentration systems, solar concentration of 2-100 suns, typically have high acceptance angles on the optical train thereby reducing the requirements for control/tracking or in some instances removing them completely. Such low concentration systems (LCPV) typically do not require cooling despite the increased operating temperature of the PV cells which increases with effective number of sun concentration. Medium concentration systems (MCPV), 100-300 suns, require solar tracking and associated control plus require cooling and hence complexity. High concentration systems (HCPV) employ concentrating optics consisting of dish reflector or Fresnel lenses that achieve intensities of 300 suns or more. As such HCPV systems require high capacity heat sinks and/or active temperature control to prevent thermal destruction and to manage temperature related performance issues.

Examples of prior art concentrators from CPV and concentrator solar thermal (CST) systems include for example C. J. Sletter in U.S. Pat. No. 4,171,695 entitled “Image Collapsing Concentrator and Method for Collecting and Utilizing Solar Energy” discloses a solar thermal energy system employing a concentrator comprising a cylindrical Fresnel lens between a receptor and the sun and an essentially elliptical reflector behind the receptor to concentrate the solar radiation to the shaped tubular receptor for heating liquid flowing within to remote terminals for electricity generation or building heating. Sletter teaches the combination of Fresnel lens and reflector disposed either side of the receptor to remove tracking for large solar systems. The design increases solar PV system costs by requiring that the PV cells be mounted and interconnected in optically transparent assemblies and thermal management of the PV cells.

L. M Fraas et al in U.S. Pat. No. 5,118,361 entitled “Terrestrial Concentrator Solar Cell Module” and L. M. Fraas in U.S. Pat. No. 7,388,146 entitled “Planar Solar Concentrator Power Module” disclose designs employing plastic Fresnel lenses in combination with a secondary concentrator element to couple to the PV cells. In U.S. Pat. No. 7,388,146 Fraas teaches a system similar to Sletter to remove tracking requirements for large PV panels to simplify their deployment. As such the concentration is low, whereas in U.S. Pat. No. 5,118,361 increased concentration is provided by requires that the solar cells be mounted with very good heat sinking due to the optical train having its focus at the small GaAs/GaSb cells. The heat sinking significantly complicating the design for large area solar cells as Fraas teaches in respect of small rectangular cells, wherein commercial GaAs fabrication is on only 75 mm (3″) or 100 mm (4″) wafers.

J-G Rhee et al in US Patent Application 2007/0,113,883 entitled “Sunbeams Concentration Lenses, Process and Apparatus for Solar Photovoltaic Generator using Concept of Superposition” teaches a concentration lens such as shown FIG. 6 by insert 650 which depicts a lens 660 that is comprised of multiple elements 665 around a central element 670. Each element 665 having grooves formed with increasing inclination as their distance from central element 670 increases. As a result the lens 660 is intended to provide a uniform illumination at the surface of the PV cell as shown by illumination graph 680. A similar approach is disclosed by Z. Schwartzman in US Patent Application 2008/0,041,441 entitled “Solar Concentrator Device for Photovoltaic Energy Generation” employing single piece prismatic optical elements which may be either reflective or transmissive in operation. Schwartzman further teaching the requirement for heat sinking for thermal management. O'Neill in U.S. Pat. No. 6,111,190 entitled “Inflatable Fresnel Lens Solar Concentrator for Space Power” taking the migration from glass to injection moulded plastic for weight reduction a step further with a very thin moulded sheet that is formed to the correct shape using gas pressure with the moulded sheet as part of a balloon.

L. C Chen in U.S. Pat. No. 6,384,320 entitled “Solar Compound Concentrator of Electric Power Generation System for Residential Homes” and U.S. Pat. No. 6,717,045 entitled “Photovoltaic Array Module Design for Solar Electric Power Generation Systems” discloses employs a compound parabolic concentrator (CPC) with an acrylic concentrating Fresnel lens to provide an initial concentration of 5× to 10× (Fresnel lens) with a subsequent 20× to 50× concentration through the CPC concentrator. Chen employing a costly cermet coated stainless steel heat exchanger to implement a CST system. L. C Chen in U.S. Pat. No. 6,653,551 entitled “Stationary Photovoltaic Array Module Design for Solar Electric Power Generation Systems” teaches a variant with dual Fresnel lenses forming part of the optical train with liquid based thermal management.

T. I Chappell et al in U.S. Pat. No. 4,200,472 entitled “Solar Power System and High Efficiency Photovoltaic Cells used therein” discloses a solar power system including a tracking platform, a concentrator, and PV cell modules. The overall PV assembly includes a heat dissipation housing which supports a silicon cell across an open end of the housing and a heat transfer block physically engages the silicon PV cells and a metallic sponge and wick is attached to the heat transfer block, with the housing being partially filled with liquid to facilitate heat removal.

As such the majority of the prior art in CPV/CST systems have addressed either concentrator designs, for example to increase effective number of suns or reduce requirements for tracking systems, or thermal management systems. Such systems within the prior art being targeted primarily to flat PV panel geometries with low concentration factor concentrators to improve performance without increased cost and complexity from tracking systems, or high concentration systems with special PV cells capable of operating at elevated temperatures or CST systems that generate electricity as a secondary step after the initial heating of a gas or liquid at the concentration point of the CST optical assembly.

As such it would be beneficial for PV systems in residential, commercial, and industrial environments to exploit solar concentrators to increase the electricity output per unit area of deployed solar cell. It would be further beneficial for such PV systems to employ low cost tracking systems to further enhance overall electrical output and be absent complex or expensive active thermal management aspects which increase cost and reduce reliability.

Accordingly it is an object of the invention to provide PV systems employing optical concentrators and tracking systems without the requirement for active thermal management.

### SUMMARY OF THE INVENTION

It is an object of the present invention to obviate or mitigate at least one disadvantage of the prior art.

In accordance with an embodiment of the invention there is provided a device comprising a cell responsive to radiation within a predetermined first wavelength range and characterized by at least first and second dimensions along axes perpendicular to one another in a plane parallel to the surface of the cell; and a lens transmissive to a predetermined second wavelength range that overlaps a predetermined portion of the predetermined first wavelength range and focusing radiation within the predetermined first wavelength range, the lens characterized by at least third and fourth dimensions along the same axes as the first and second dimensions respectively wherein at least one of the third dimension and fourth dimension is larger than the corresponding first dimension and second dimension, wherein in operation the lens has a predetermined separation from the cell and the plane of the lens is offset by a predetermined non-zero angle with respect to the plane of the cell.

In accordance with another embodiment of the invention there is provided a device comprising a base, the base for at least one of mounting the device to a structure and insertion into the ground, a mount mounted upon the base and comprising at least a frame and an altitude mechanism, the altitude mechanism for adjusting the elevation of the frame with respect to the base, and a controller for controlling at least the altitude mechanism and an azimuth mechanism, the azimuth mechanism for adjusting the rotational position of the frame with respect to the base. The device also comprising a cell attached to the frame and responsive to radiation within a predetermined first wavelength range and characterized by at least first and second dimensions along axes perpendicular to one another in a plane of parallel to the surface of the cell, and a lens attached to the frame and transmissive to a predetermined second wavelength range that overlaps a predetermined portion of the predetermined first wavelength range and focusing radiation within the predetermined first wavelength range, the lens characterized by at least third and fourth dimensions along the same axes as the first and second dimensions respectively wherein at least one of the third dimension and fourth dimension is larger than the corresponding first dimension and second dimension, wherein in operation the lens has a predetermined separation from the cell and the plane of the lens is offset by a predetermined non-zero angle with respect to the plane of the cell.

In accordance with another embodiment of the invention there is provided a device comprising a base, the base for at least one of mounting the device to a structure and insertion into the ground, a mount mounted upon the base and comprising at least a frame and an altitude mechanism, the altitude mechanism for adjusting the elevation of the frame with respect to the base and a controller for controlling at least the altitude mechanism and an azimuth mechanism, the azimuth mechanism for adjusting the rotational position of the frame with respect to the base. The device further comprising a cell attached to the frame and responsive to radiation within a predetermined first wavelength range and characterized by at least first and second dimensions along axes perpendicular to one another in a plane of parallel to the surface of the cell, a lens attached to the frame and transmissive to a predetermined second wavelength range that overlaps a predetermined portion of the predetermined first wavelength range and focusing radiation within the predetermined first wavelength range, the lens characterized by at least third and fourth dimensions along the same axes as the first and second dimensions respectively wherein at least one of the third dimension and fourth dimension is larger than the corresponding first dimension and second dimension, wherein in operation the lens has a predetermined separation from the cell and the plane of the lens is offset by a predetermined angle with respect to the plane of the cell, and a reflector comprising at least an inner surface and an outer surface and having a first end disposed towards the cell and a distal end disposed towards the lens, the first end having a geometry determined in dependence upon at least the geometry of the cell and the inner surface being reflective to radiation within the predetermined first wavelength range, wherein in operation an axis of the reflector along which the first end and distal end are disposed is offset at a predetermined non-zero angle with respect to an axis between a centre of the lens and a centre of the cell.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 depicts average annual solar energy worldwide;

FIG. 2 depicts the solar radiation across the continental United States together with projected pricing for solar and fossil fuel generated electricity for 2006-2020 and the sources of electricity globally in 1980 and 2006;

FIG. 3 depicts the evolution of photovoltaic cell efficiencies for different semiconductor technologies;

FIG. 4 depicts the cost of solar panels in Europe and North America (2001-2009) together with the thickness and consumption of silicon for solar cell manufacturing (2004-2010) in conjunction with projected 2015 targets for the US National Solar Technology Roadmap;

FIG. 5 depicts typical current solar cell deployment scenarios together with the daily output of fixed orientation flat solar panels with time of day;

FIG. 6 depicts a solar concentrator according to the prior art of Green (US Patent Application 2009/0,272,425) and multi-element Fresnel lenses according to Green and—G Rhee et al in US Patent Application 2007/0,113,883;

FIG. 7 depicts a schematic of a solar power generator according to an embodiment of the invention;

FIG. 8 depicts a schematic of a solar power generator according to an embodiment of the invention from above;

FIG. 9 depicts a schematic of a solar power generator according to an embodiment of the invention with the upper portion of the housing removed;

FIG. 10 depicts the elevation of the optical train within a solar power generator according to an embodiment of the invention as the year progresses;

FIG. 11 depicts the orientation of the optical train within a solar power generator according to an embodiment of the invention during the course of a day;

FIG. 12A depicts a concentrator lens design and associated optical ray diagram for a solar power generator according to an embodiment of the invention;

FIG. 12B depicts a concentrator lens design and associated optical ray diagram for a solar power generator according to an embodiment of the invention;

FIG. 12C depicts a concentrator lens design and associated optical ray diagram for a solar power generator according to an embodiment of the invention;

FIG. 12D depicts a model for segmenting a concentrator lens design for a solar power generator according to an embodiment of the invention for analysis;

FIG. 13 depicts optical ray diagrams for a concentrator lens design rotated at different angles with respect to the plane of a PV cell;

FIG. 14 depicts a triple concentrator lens design according to an embodiment of the invention;

FIG. 15A depicts a design and ray diagram for a reflective baffle according to an embodiment of the invention;

FIG. 15B depicts a design and ray diagram for a reflective baffle according to an embodiment of the invention;

FIG. 16 depicts ray diagrams for a concentrator lens according to an embodiment of the invention wherein the PV cell is disposed at two different locations relative to the lens;

FIG. 17 depicts two PV cell designs for use within solar power generators according to embodiments of the invention;

FIG. 18 depicts a solar power generator according to an embodiment of the invention employing three optical trains; and

FIG. 19 depicts a concentrator lens according to an embodiment of the invention.

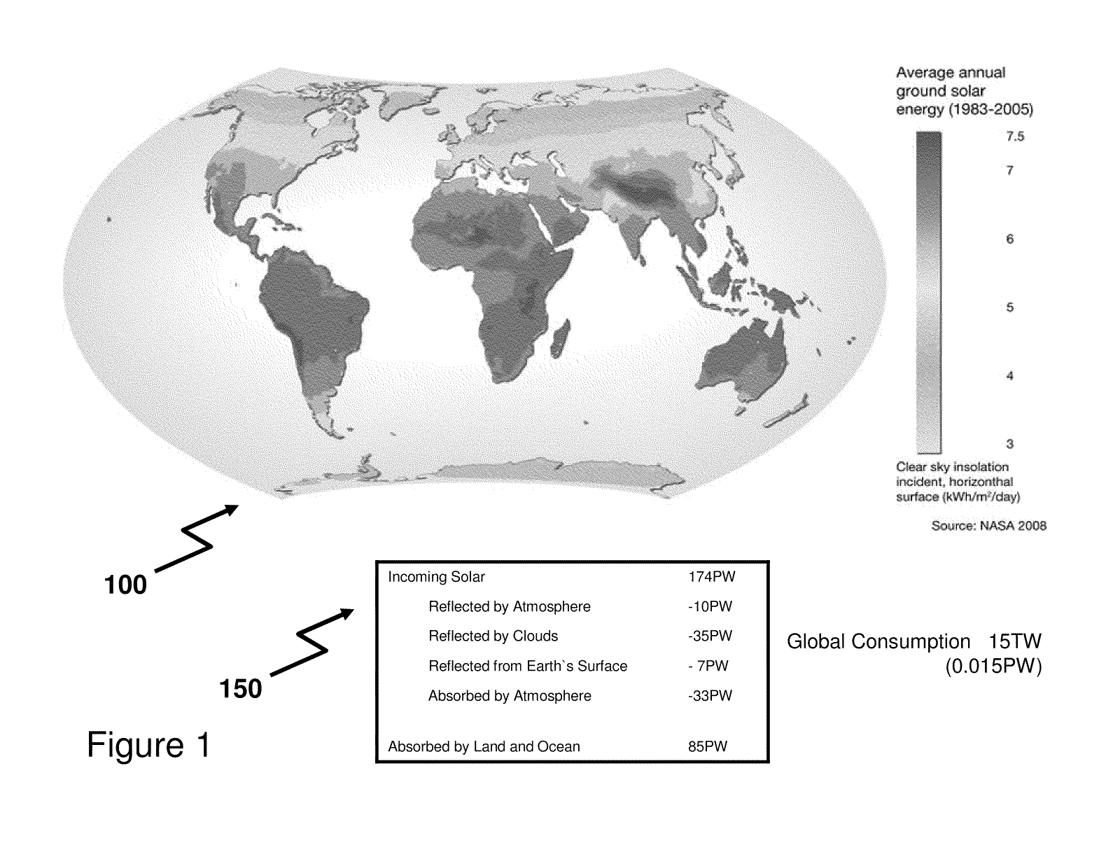

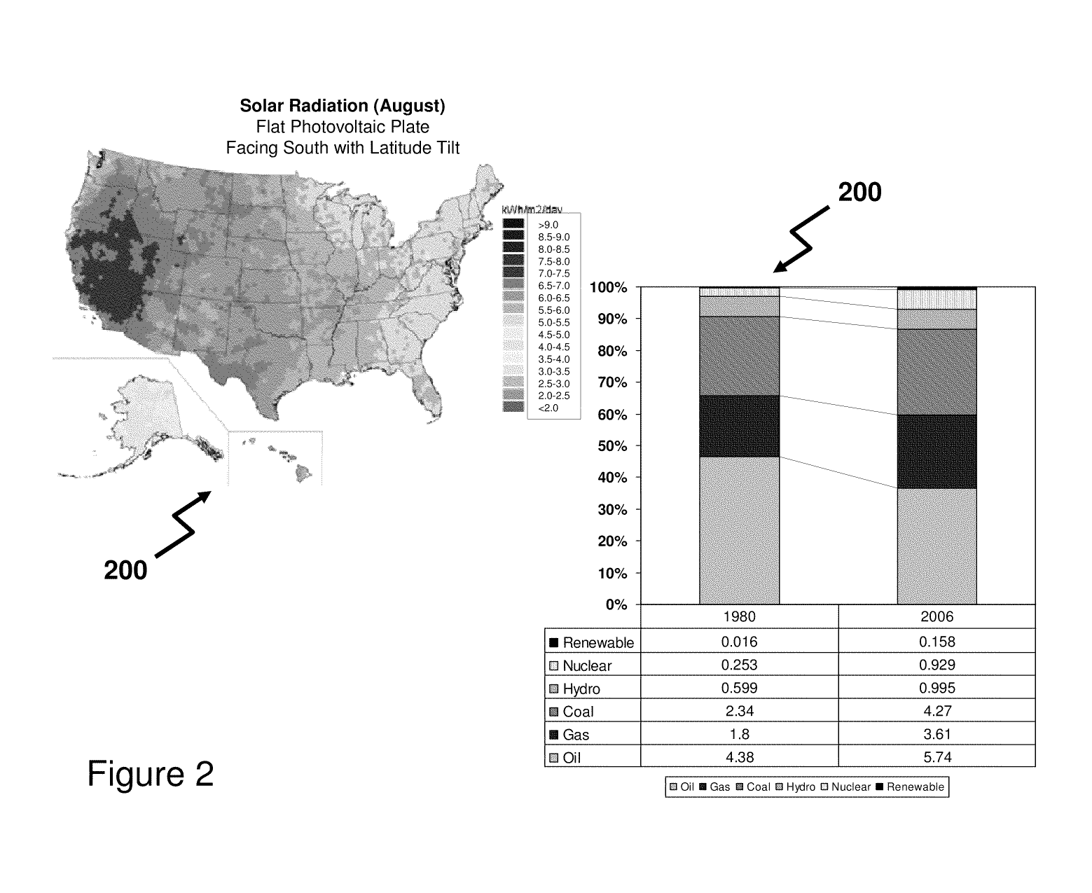

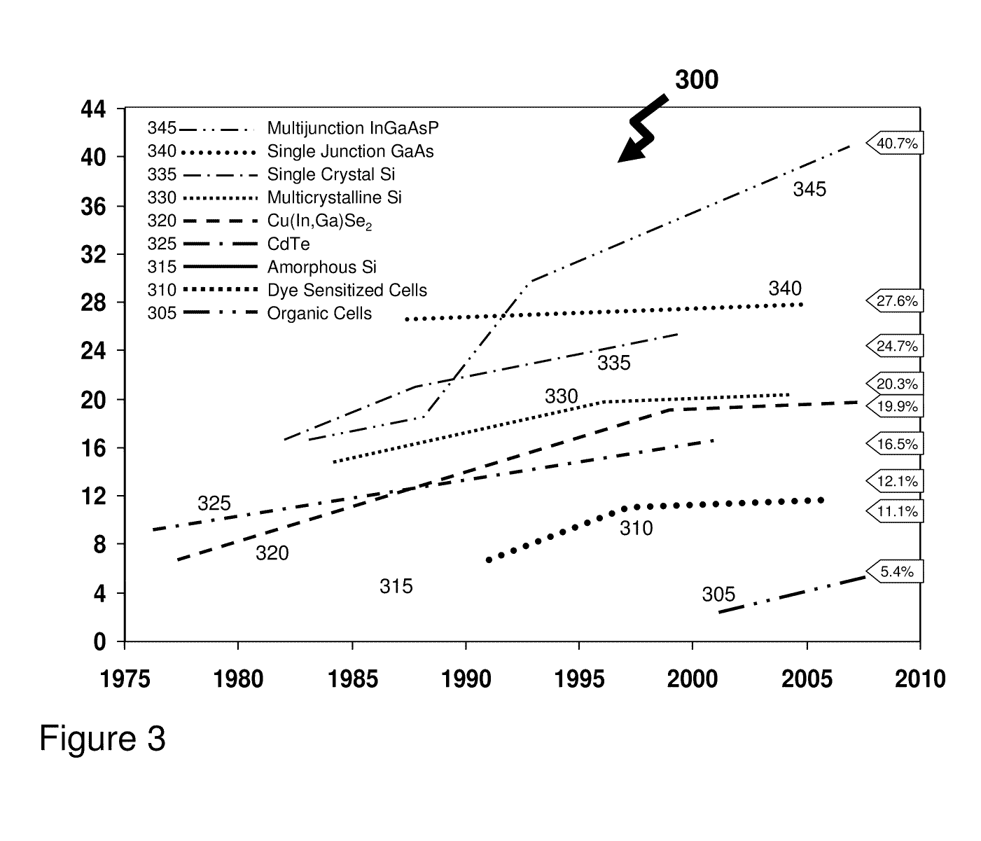

### DETAILED DESCRIPTION

The present invention is directed to providing a compact solar power concentrator with chronological tracking without requiring active thermal management.

Reference may be made below to specific elements, numbered in accordance with the attached figures. The discussion below should be taken to be exemplary in nature, and not as limiting of the scope of the present invention. The scope of the present invention is defined in the claims, and should not be considered as limited by the implementation details described below, which as one skilled in the art will appreciate, can be modified by replacing elements with equivalent functional elements.

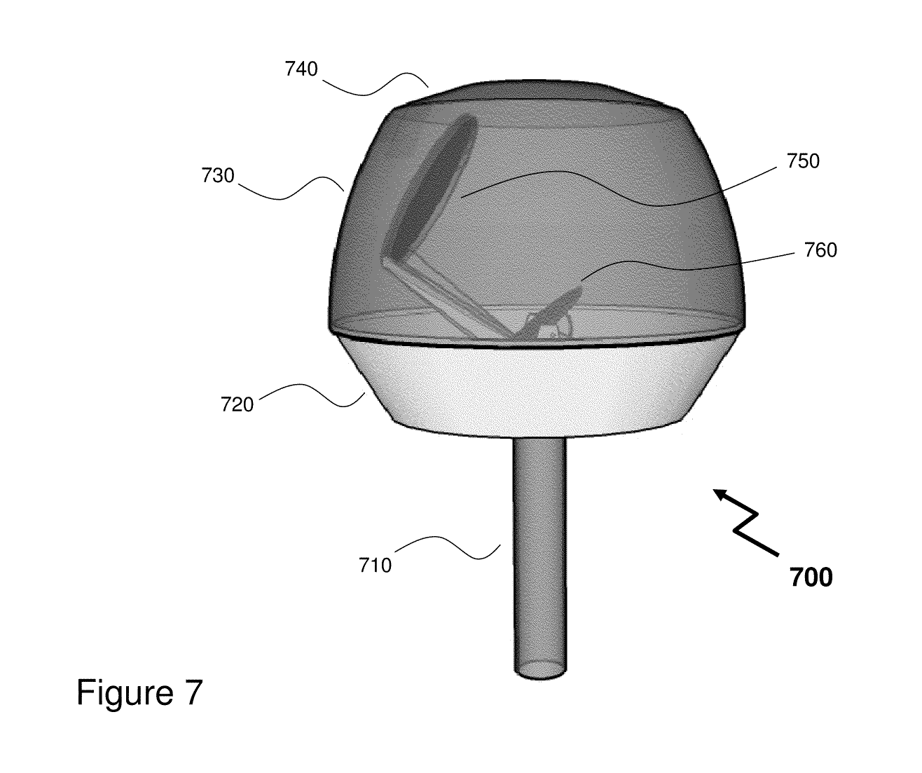

Illustrated in FIG. 7 is a solar power generator 700 according to an embodiment of the invention. As shown solar power generator 700 comprises a mounting post 710, lower external body 720, upper external body 730, and lid 740. Upper external body 730 and lid 740 are transparent to at least significant portion of the wavelength spectrum for the PV cells within the solar power generator 700. For example if the PV cells are α-Si then the upper external body 730 and lid 740 would be transparent to at least significant portions of the visible spectrum as silicon solar cells are responsive from approximately 400 nm to 700 nm. If the PV cells are GaAs transparency would be 450 nm to 900 nm, and for CuInSe₂/CdSe (CIS) transparency would be 500 nm into the near infra-red at 1250 nm. Suitable materials for the external body 730 and lid 740 would be polycarbonate and acrylic (Poly-methyl methacrylate—PMMA). Within the shell formed by lower external body 720, upper external body 730, and lid 740 is the solar assembly comprising at least concentrator lens 750 and PV assembly 760.

It would be apparent to one skilled in the art that the upper external body 730 and lid 740 may alternatively be formed as a single piece-part, for example as a single injection moulded polycarbonate dome. Optionally the lower external body 720 may be formed from the same material but as it does not have to be transparent to the operating wavelength of the PV cells the choices of materials are wider including but not limited to non-optically transparent plastics and metals.

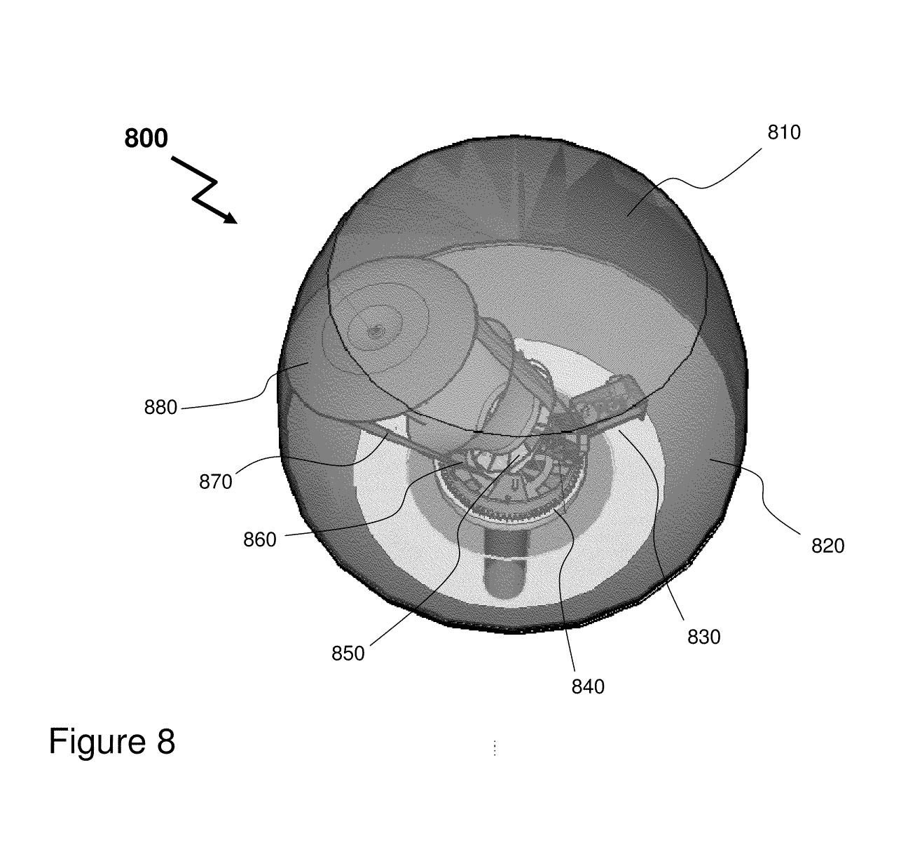

Now referring to FIG. 8 there is depicted a schematic of a solar power generator 800 according to an embodiment of the invention from above with the lid removed, such as lid 740 of FIG. 7 above. As shown the solar power generator 800 comprises an external housing formed from upper external body 810 and lower body 820. The generating portion of the solar power generator 800 begins with concentrator lens 880 which is mounted upon frame 870. Also attached to frame 870 is reflector 860 which directs concentrated solar radiation to the PV assembly 850. The frame 870 is mounted onto azimuth gear 840 which rotates the solar assembly for daily rotation of the solar assembly to track the sun. Azimuth gear 840 being controlled from controller 830.

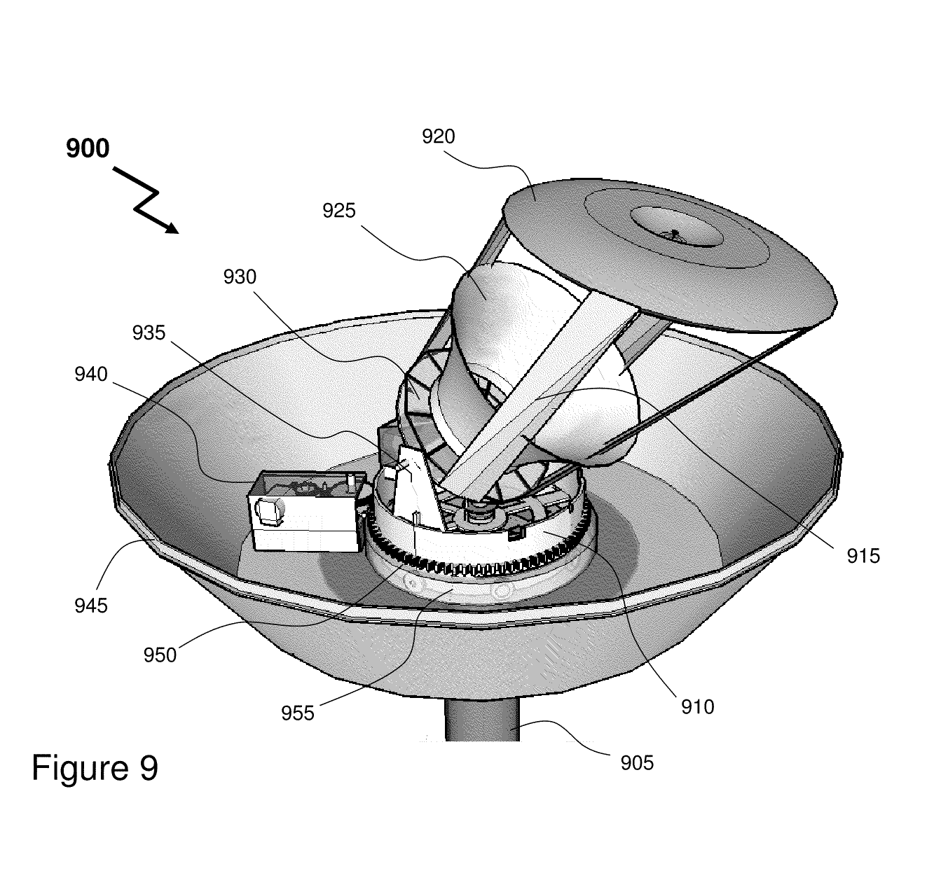

Now referring to FIG. 9 there is depicted a solar power generator 900 according to an embodiment of the invention with the upper portion of the protective housing removed. As such solar power generator 900 comprises a post 905 which has attached lower housing 945. Mounted to the top of post 905 is mounting 955 which supports the solar assembly and allows rotation to track the daily motion of the sun. For example mounting 955 may be a ball bearing mount to allow low friction rotation of the upper assembly whilst driven by gear 950 on the lower frame 910 through control of gear drive controller 940. Lower frame 910 then supports altitude frame 935 which adjusts the altitude of the solar assembly to provide adjustment for inclination of the sun during the year. Gear drive controller 940 would be programmed according to the location of the solar power generator 900.

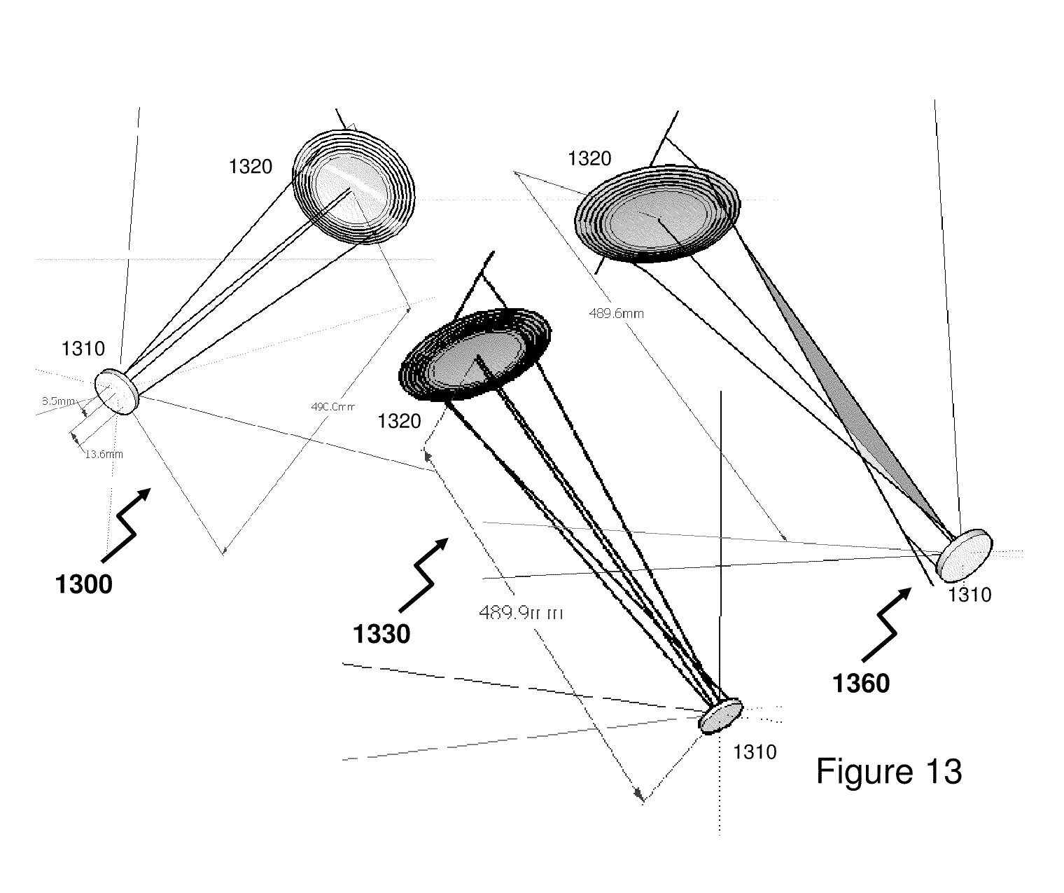

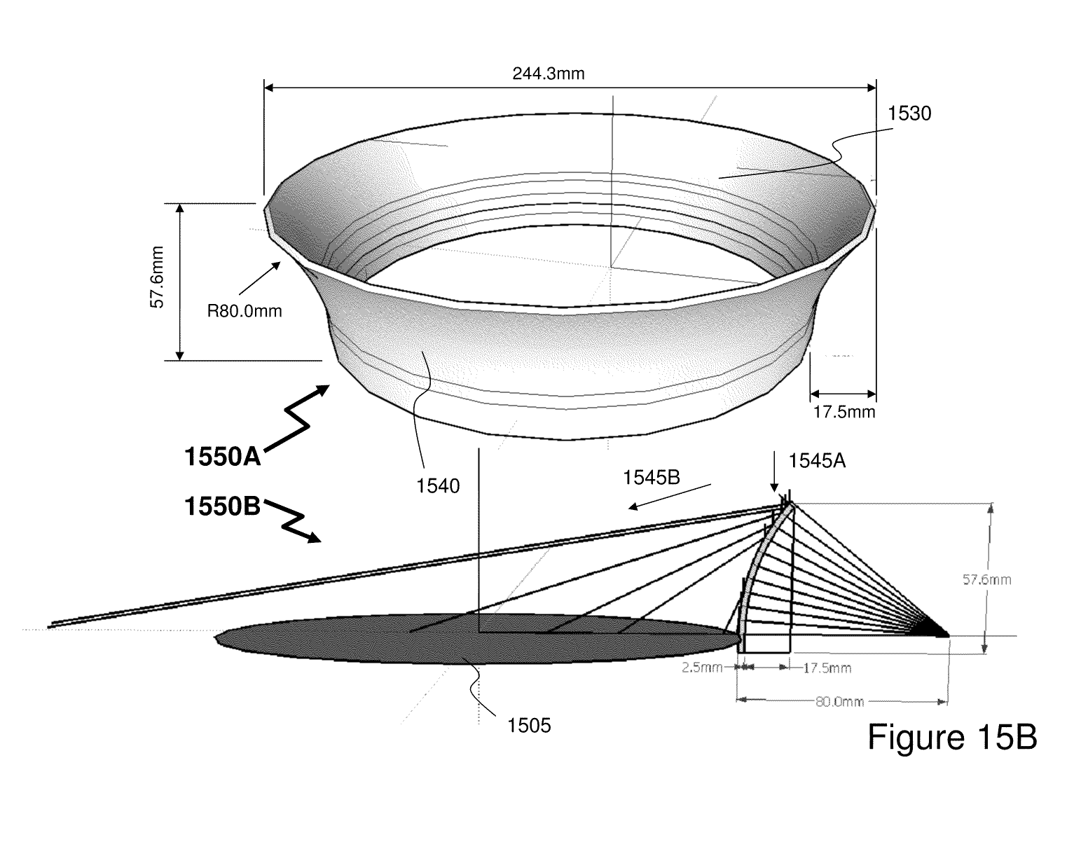

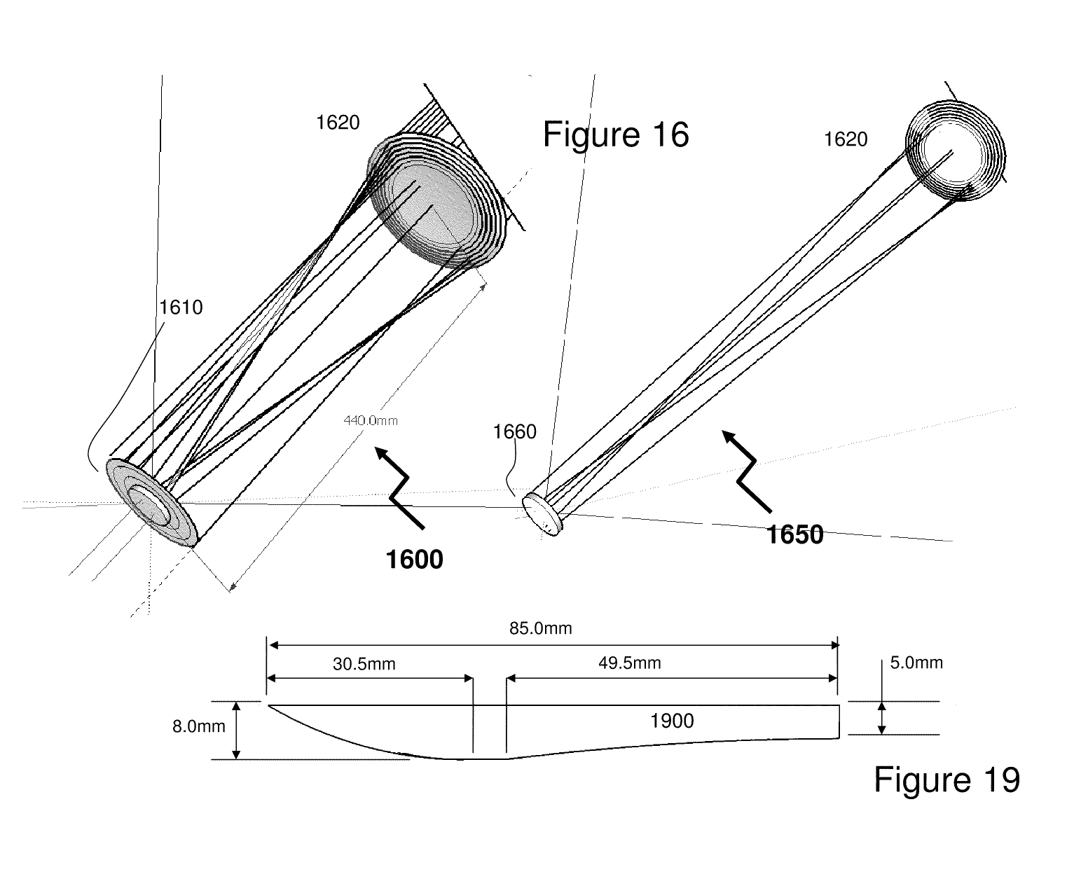

Mounted upon altitude frame 935 is solar assembly frame 915 supported from a base plate 930 of the solar assembly. The base plate 930 also has mounted atop it the PV cells of the solar power generator 900, not shown for clarity. Attached at a predetermined position on the solar assembly frame 915 is reflector 925 and at the top of the solar assembly frame is lens 920. Accordingly solar radiation impinging upon lens 920 is directed towards the PV cells mounted on the base plate 930, and optical signals concentrated off-axis are reflected by reflector 925 towards the PV cells such as shown in FIGS. 13 and 16 below.

It would be apparent from FIG. 9 that lens 920 is not disposed parallel to base plate 930 and accordingly the PV cell mounted thereupon. The inventor has discovered that rotating the lens 920 away from such parallelism to the PV cell results in a significant increase in the generated photocurrent from the PV cell. For example, using a simple 150 mm (6″) plano-concave-convex lens with an annular prismatic ring in conjunction with a 50 mm square (2″ square) at distances between 18 cm and 94 cm the inventor observed a significant increase in generated photocurrent as the lens was rotated away from parallel to the PV cell with a maximum at approximately 20 degrees offset at a separation of 49 cm. With the lens in this configuration a further increase in generated photocurrent was observed when flat mirrors were disposed around the PV cell to form a simple square cone. As shown a first diametric axis of the circular lens 920 is aligned along the plane of the PV cell(s) and then is rotated about the second transverse diametric axis by the predetermined rotational offset in either a clockwise or counter-clockwise direction. It would be evident that lens 920 may for example be an injection moulded polycarbonate lens.

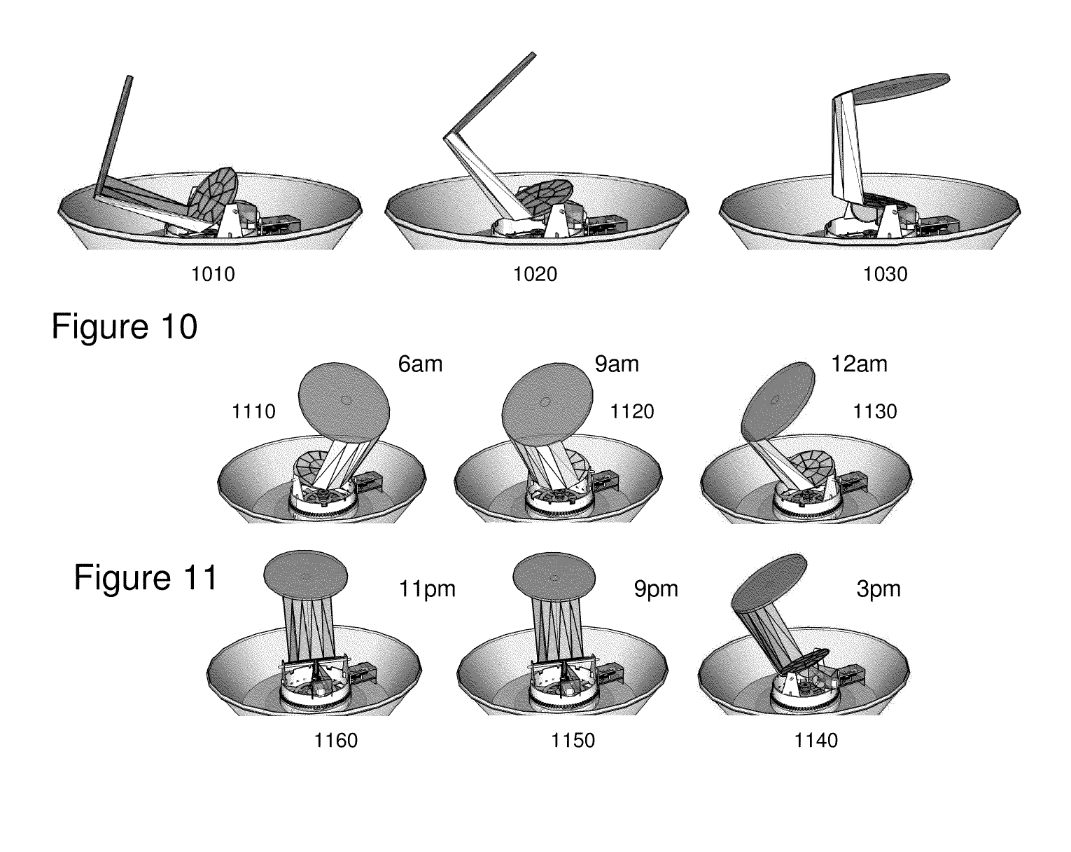

Referring to FIG. 10 there are depicted views of a solar power generator, such as solar power generator 900 in FIG. 9, according to an embodiment of the invention as the year progresses. In first view 1010 the solar power generator is shown in a setting representing winter for a deployment within northern United States such as Buffalo, Detroit, Chicago, St Paul and Seattle or lower Canada, such as Ottawa, Toronto, Montreal and Vancouver. Next in second view 1020 the solar power generator is shown in a setting representing spring or fall with the solar assembly raised in altitude. In third view 1030 the solar power generator is shown in a setting representing summer setting.

In FIG. 11 there are depicted orientations of the optical train within a solar power generator according to an embodiment of the invention during the course of a day, the solar power generator being for example such as described supra in respect of solar power generator 900 in FIG. 9. As such there are shown first to sixth views 1110 to 1160 respectively which represent azimuth settings for the solar assembly at 6 am, 9 am, 12 am, 3 pm, 9 pm and 11 pm. The azimuth-altitude control of the solar power generator allows the optical train to be orientated so that the electrical output is maintained during the daily and seasonal variations of the sun's position with respect to the solar power generator such that the highest possible electrical current is achieved in the smallest space without generating high temperatures. As such the azimuth-altitude control orientates the solar assembly (lens, reflector, and PV cells) with the dual axis rotator comprised for example from altitude frame 935 and lower frame 910 of FIG. 9. The daily and yearly rotations are controlled for example by digital programmable timers and proximity sensors or switches. Daily rotation is from east to west with increments established for example between 1 second of rotation and 2 minutes of rotation for more efficient operation.

The shorter the increments employed the higher the efficiency of the solar power generator but also the higher the drain on generated electrical power from the driving elements of each of the altitude and azimuth rotators. Yearly rotation is represented by the sun's location oscillating between the horizon and directly above and controlled for example by increments set between 2 days to 15 days to always maintain an adequate direct orientation with the sun in the northern hemisphere. Chronologic circuitry is used to control the settings for rotational alignment of the solar power generator. The extent of rotation varies according to the location of the solar power generator. It would be evident to one of skill in the art that once deployed with the chronologic circuit engaged with settings dependent upon location that minimal intervention would be required except in odd occurrences. Optionally the controller may be provided with a wireless interface or electrical interface allowing resetting of control parameters or triggering a jogging reset for example.

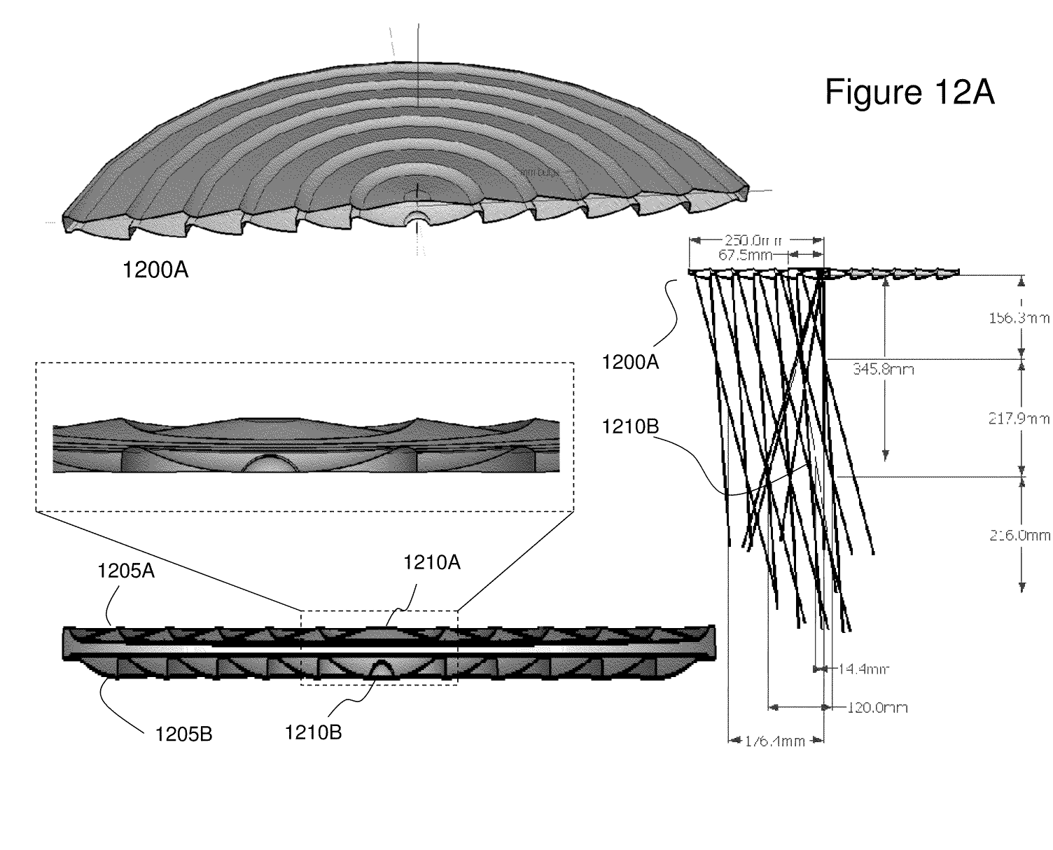

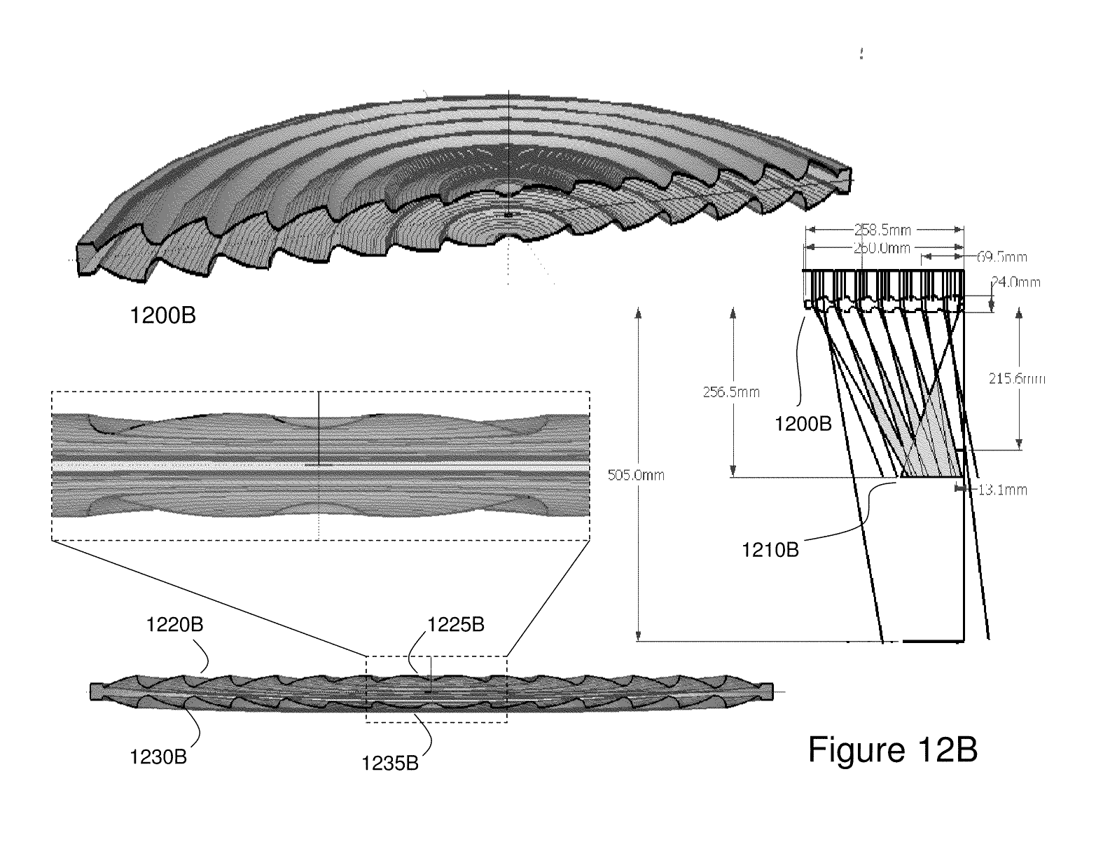

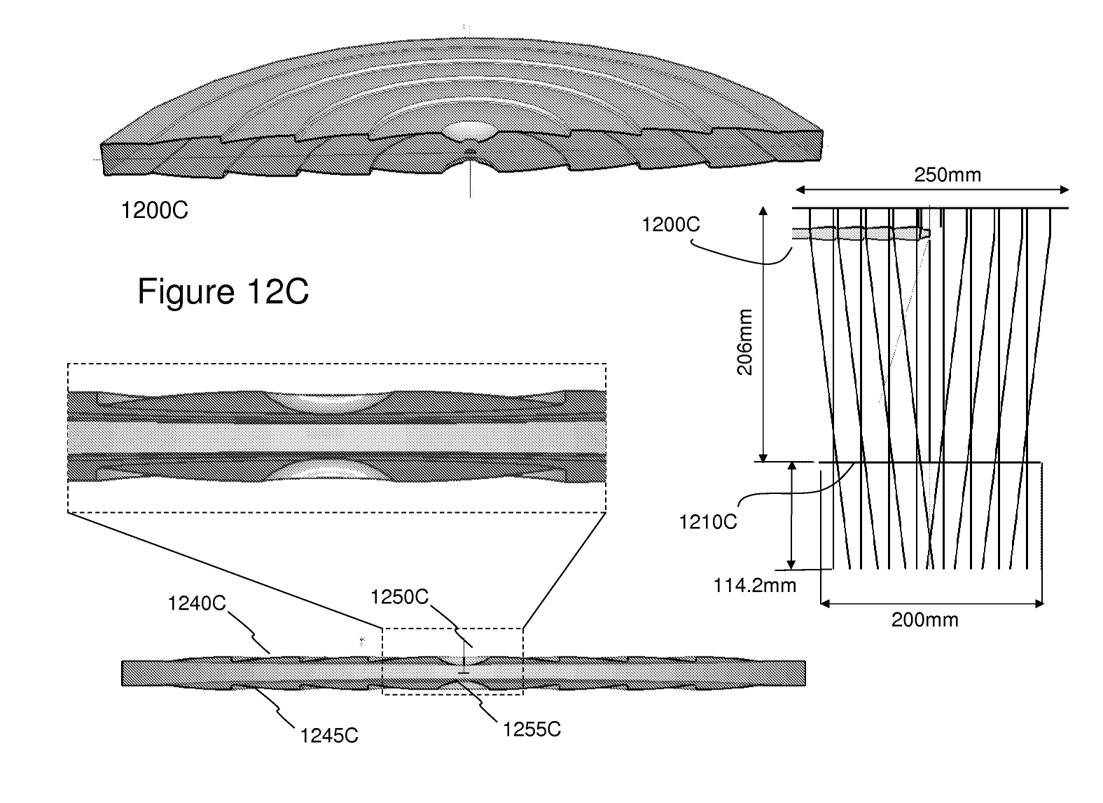

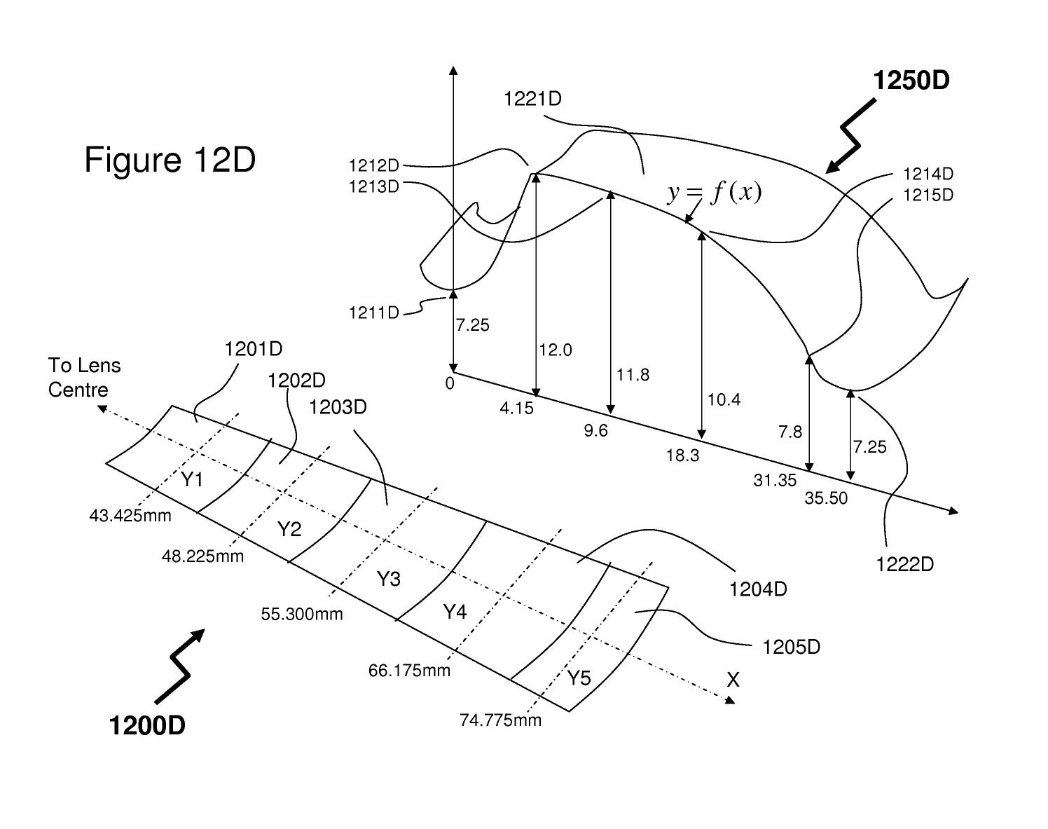

Referring to FIG. 12A through to FIG. 12C there are depicted exemplary concentrator lens designs for solar power generators according to embodiments of the invention. Considering initially FIG. 12A there is shown a concentrator lens 1200A according to an embodiment of the invention presented in three-dimensional section and cross-section views. As shown the concentrator lens 1200 consists of a central circular core region surrounds by a series of 5 concentric rings. The central circular core comprising an upper portion 1210A and lower portion 1210B has a diameter of 40 mm. Lower portion 1210B has a convex section removed which penetrates to a depth of 5.8 mm into the lens body. The 5 concentric rings each comprise an upper profile 1205A and lower profile 1205B and have a width overall of 40 mm. Upper profile 1205 consists of a linear reducing profile with increasing radius with a slope of 4.5 mm over a distance of 30 mm. The upper profile 1205A then curves and returns the full thickness of the concentrator lens 1200A. In contrast lower profile 1205B consists initially of an arc section of length 33 mm that reduces the concentrator lens 1200 thickness by 8 mm at the outer edge of this arc section before curving back to the full thickness of the concentrator lens 1200. The lens having a maximum thickness of 18 mm and terminating after the fifth concentric ring in a flat mounting ring of thickness 11 mm and width 30 mm giving an overall lens diameter of 500 mm. Also shown is the ray diagram for concentrator lens 1200A with a PV cell placed at a separation of 345.8 mm away.

Now referring to FIG. 12B there is shown a concentrator lens 1200B according to an embodiment of the invention presented in three-dimensional section and cross-section views. As shown the concentrator lens 1200B consists of a central circular core region surrounded by a series of 6 concentric rings. The central circular core comprising an upper portion 1225B and lower portion 1225A has a diameter of 40 mm, each of which have a convex section removed which penetrates to a depth of 3.0 mm into the lens body. The 6 concentric rings each comprise an upper profile 1220B and lower profile 1220A and have an overall width of 35.5 mm. Each of the upper profile 1220B and lower profile 1220A consist of a convex profile with decreasing radius such that at their limit at increased radius they have increasing depth into the body of the lens, having maximum depth from planar surface profile of 4.3 mm, 4.7 mm, 6.8 mm, 7.9 mm, 8.5 mm and 8.9 mm respectively. The rim of concentrator lens 1200B comprises a region 9 mm wide and 12 mm thick. Concentrator lens 1200B having a thickness of 24 mm at its thickest. Also shown is the ray diagram for concentrator lens 1200B with PV cell 1210B disposed 256.5 mm away.

Referring to FIG. 12C there is shown a concentrator lens 1200C according to an embodiment of the invention presented in three-dimensional section and cross-section views. As shown the concentrator lens 1200C consists of a central circular core region surrounds by a series of 4 concentric rings. The central circular core comprising an upper portion 1250C and lower portion 1255C has a diameter of 40 mm. Each of the upper portion 1250C and lower portion 1255C has a convex section removed which penetrates to a depth of 3 mm into the lens body and has a radius of 14.9 mm. The 4 concentric rings each comprise an upper profile 1240C and lower profile 1245C and have an overall width of 25 mm. Each of the upper profile 1240C and lower profile 1245C consist of a large radius convex surface such that in combination they reduce the lens thickness at the outer edge of each concentric ring the lens thickness is reduced to 8.3 mm from its 12 mm thickness at the inner edge of each concentric ring. Additionally shown to the three-dimensional section and cross-section views there is shown the ray diagram for concentrator lens 1200C showing the PV cell 1210C.

Now referring to FIG. 12D there is shown sectional view 1250D and plan view 1200D for a section of a concentrator lens such as the outermost portion of upper profile 1220B and lower profile 1220A representing the outermost portion of a concentric ring of lens 1200B. In plan view 1250D that section of the concentrator lens is shown broken into 5 sections being sections 1201D through 1205D, each marked with a distance from the centre of the lens by distances 43.425 mm, 48.225 mm, 55.3 mm, 66.175 mm, and 74.175 mm respectively where such sectioning of the lens has been used in generating the profiles used within forming ray diagrams in FIGS. 12A through 12D. As will be discussed below the volume of the lens factors into the relationship of the concentrator lens and its angular offset from the plane parallel to the PV cell. In sectional view 1250D the lens surface 1221D is shown having a profile defined by a mathematical function y=f(x) where x is the distance from the lens centre and y the thickness of the lens from its centre line. As shown this function passes through P(0, 7.25) 1211D, P(4.15, 12.0) 1212D, P(9.6, 11.8)) 1213D, P(18.3, 10.4) 1214D, and P(31.35, 7.8) 12215D and then passes through the beginning of the next concentric ring at P(35.5, 7.25)) 1222D. As such lens surface 1221D representing the surface of either upper profile 1220B or lower profile 1220A of concentrator lens 1200B.

Accordingly to calculate the volume of one lens ring for concentrator lens 1200B we use Equation 1 below:

V_{LENS}=RingCircumference×RingCrossSectionArea (1)

which is approximated for N sections as Equation (2) below:

V_{LENS}/2=2πr₁A₁+2πr₂A₂+2πr₃A₃+ . . . 2πr_{N}A_{N} (2)

Using the data presented supra in respect of lens surface 1221D we obtain

$$\frac{{V}_{LENS}}{2} = 2 π {r}_{1} {\int }_{0}^{4.15} f ( x ) d x + 2 π {r}_{1} {\int }_{4.15}^{9.6} f ( x ) d x + 2 π {r}_{1} {\int }_{9.6}^{18.3} f ( x ) d x + 2 π {r}_{1} {\int }_{18.3}^{31.35} f ( x ) d x + 2 π {r}_{1} {\int }_{31.35}^{35 , 5} f ( x ) d x$$

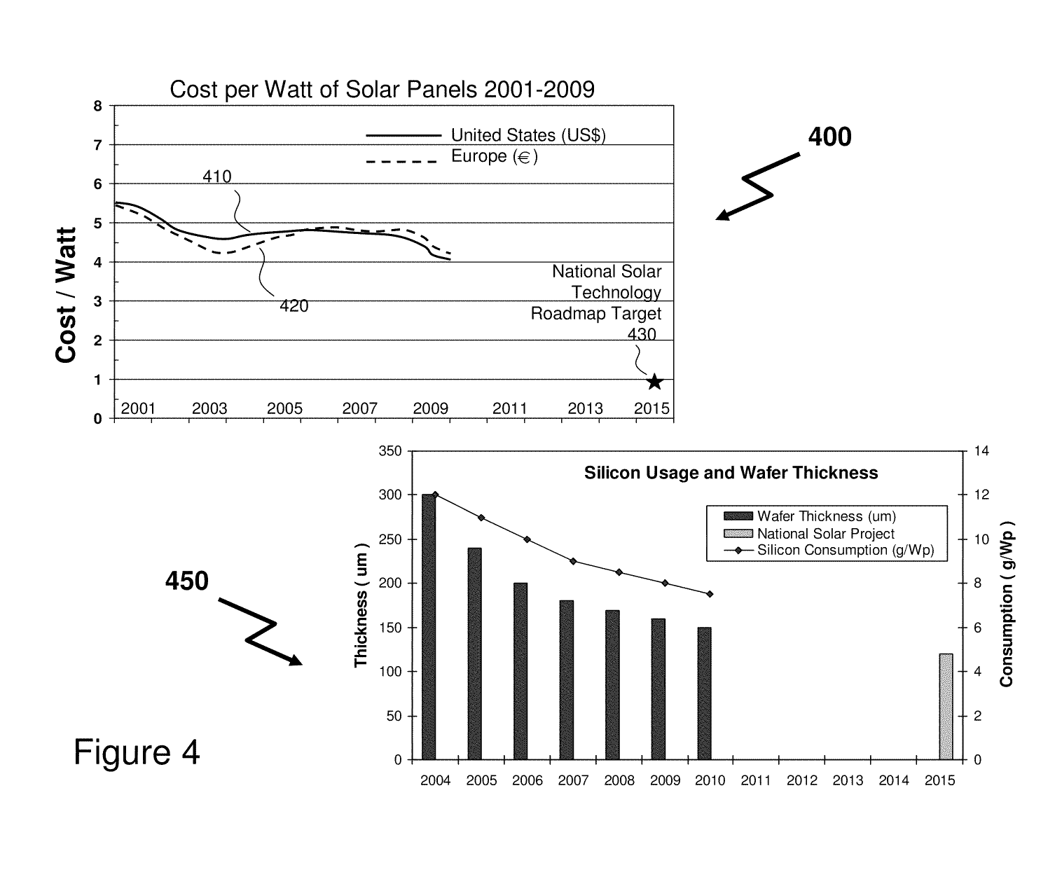

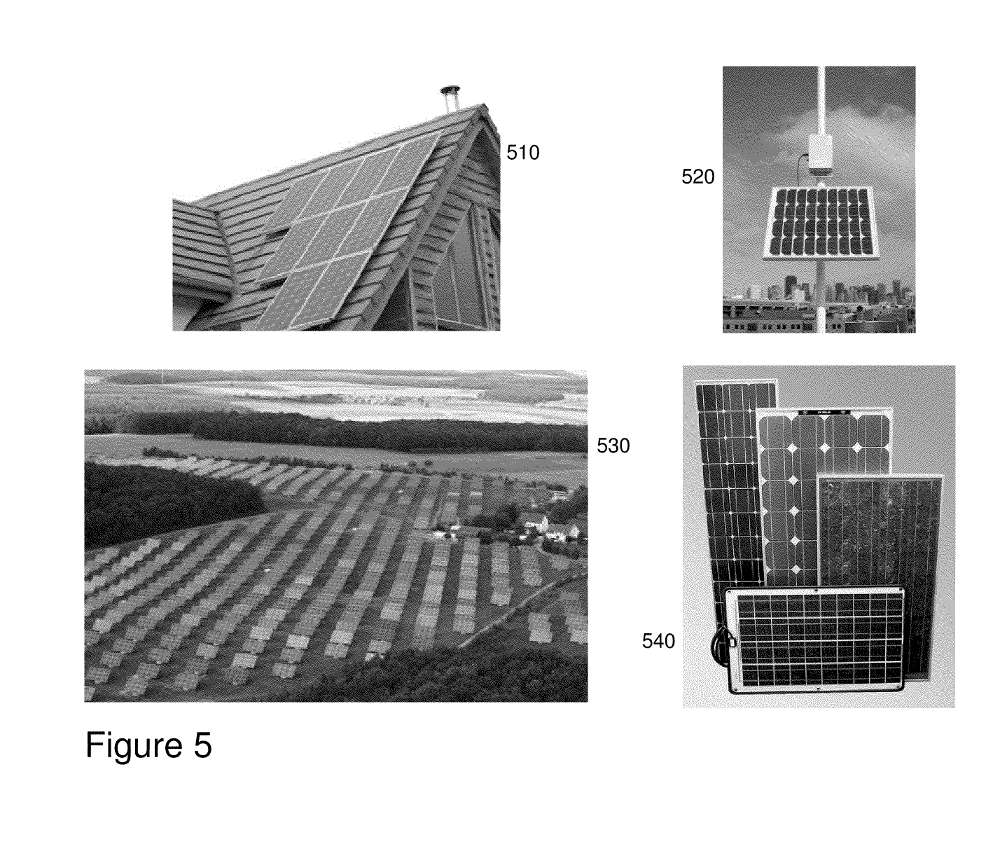

such that V_{LENS}≈2.56×10¹⁴ μm³. Similarly the volume of the PV cell considering a circular 2″ (50.8 mm) diameter wafer of thickness 300 um results in a wafer volume of V_{PV}=2πR²t_{PV}≈6.08×10¹¹ μm³, where R is the radius of the PV cell and tₚ is the wafer thickness. The inventors have established that tilting of the concentrator lens is beneficially implemented with thick concentrator lenses, such as described supra in respect of FIGS. 12A through 12C being at least 0.3″ (8 mm) thick rather than thin lenses (i.e. 0.1″ (2.5 mm) thick or less). Similarly the silicon wafer in contrast to the trend discussed supra in respect of FIG. 4 should be beneficially thick, i.e. 300 μm or thicker, allowing good dissipation of heat generated within the solar power generator. Further, it is beneficial to not include any plastic encapsulation, even if clear, due to the increase in temperature and potential long term degradation of the plastic through ultraviolet radiation etc.

It would be apparent to one skilled in the art that the concentrator lens may be implemented with a variety of lens designs ranging from simple through to complex. Further the concentrator lens may be implemented as a single element or as a compound element. It would also be apparent that the lens may be manufactured from glass but for weight reduction and potentially cost reductions from injection moulding that the lens may be formed from a plastic having a suitable transmission window with respect to the wavelength sensitivity of the PV cells. Potential plastics include for example clear polystyrene, acrylic, SAN, PETG, elastomeric materials or polyester. It would also be apparent that manufacturing the plastic lens or lens elements with a small amount of carbon black additive or other processes well know to those skilled in the art may reduce significantly the degradation of transmission efficiency over time from ultraviolet radiation.

In operation the plurality of lens sections provide a series of luminous rings on the PV cell which contribute to electrical output current and a series of dark rings which do not. If the concentration of the lens is high then the focused luminous rings may saturate locally the PV cell such that the increased solar energy is not utilized in generating electricity but rather generates heat within the solar power generator. Accordingly the inventor has identified that an increase in output can be achieved by rotating the lens with respect to the surface of the PV cell such that these luminous rings are distributed. The particular rotation and separation of the lens being dependent upon the design of the lens, optical properties, etc as well as factors such as PV cell geometry. Adjustment of the distance between lens and solar panel also allows the solar power generator to operate at safe temperatures while generating maximum current and removing the requirement for active heat sinking. For example a lens design with a central concave surface keeps the centre of the solar panel relatively cool while refracting as many diverging rays as possible at the centre of each panel.

As such by increasing the concentration power of the lens, and rotating the lens, for example at an angle between 10 degrees and 60 degrees off axis with respect to the plane parallel to the PV cell increases the current from the PV cell y avoiding saturation effects, degradations through thermal issues, etc. Referring to FIG. 13 there are shown 10 degree rotated ray diagram 1300, 15 degree rotated ray diagram 1330 and 30 degree rotated ray diagram 1360 all of which comprise 150 mm concentrator lens 1320 and PV cell 1310. Beneficially the inventor has found that rotating the concentrator lens out of the plane taught by the prior art provides for a reduction in the “length” of the optical train such that the solar power generator incorporating embodiments of the invention is smaller. For example using a 6″ (150 mm) diameter concentrator lens with a 2″ (50 mm) PV cell and rotating the lens to approximately 30 degrees allowed the separation between concentrator lens and PV cell to be approximately 17″ (430 mm). Without rotating the concentrator lens the separation had to be increased to approximately 44″ (1110 mm). In each case the assembly position being established such that maximum electrical current was generated in the PV cell without the requirement for any forced cooling of the PV cell or its assembly. Within the embodiments discussed supra and below analysis has typically been presented in respect of rotating the lens along a single with respect to the plane of the PV cell. It would be apparent that the concentrator lens may be rotated in both axes respective to the PV cell. Optionally the PV cell may be rotated whilst the concentrator lens is maintained approximately perpendicular to the incident solar radiation or both the concentrator lens and PV cell are rotated off-axis with nominal planes perpendicular to the incident solar radiation.

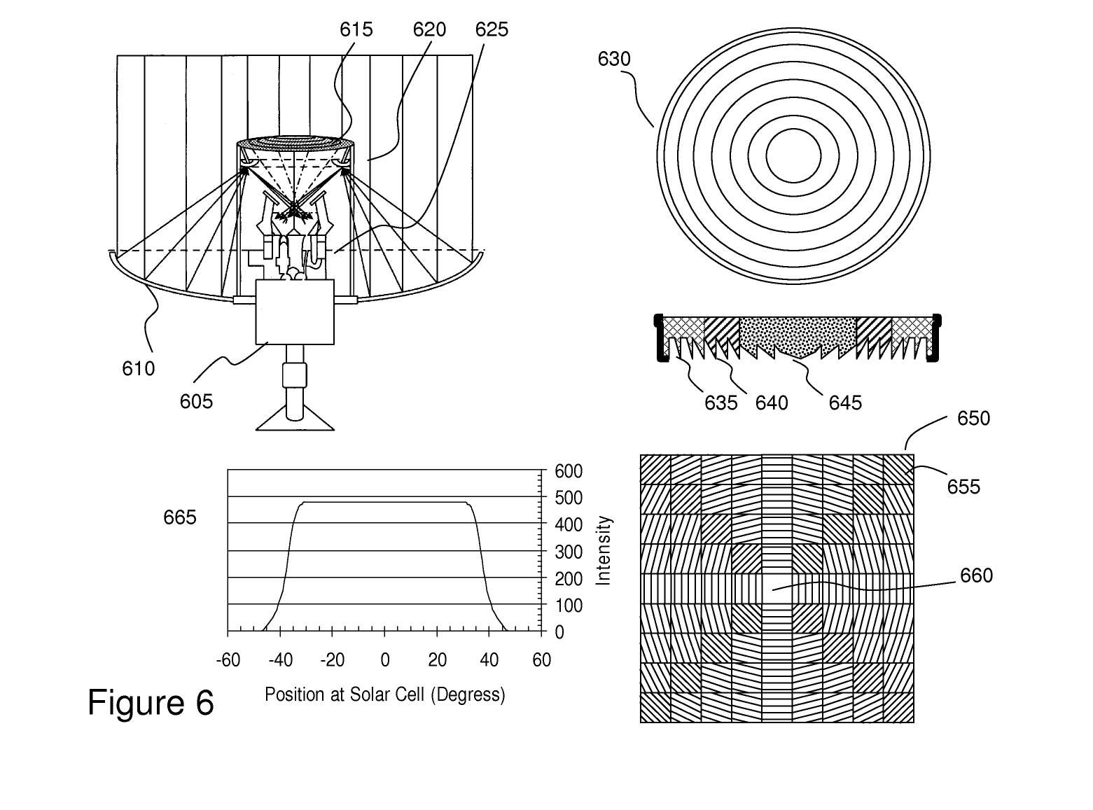

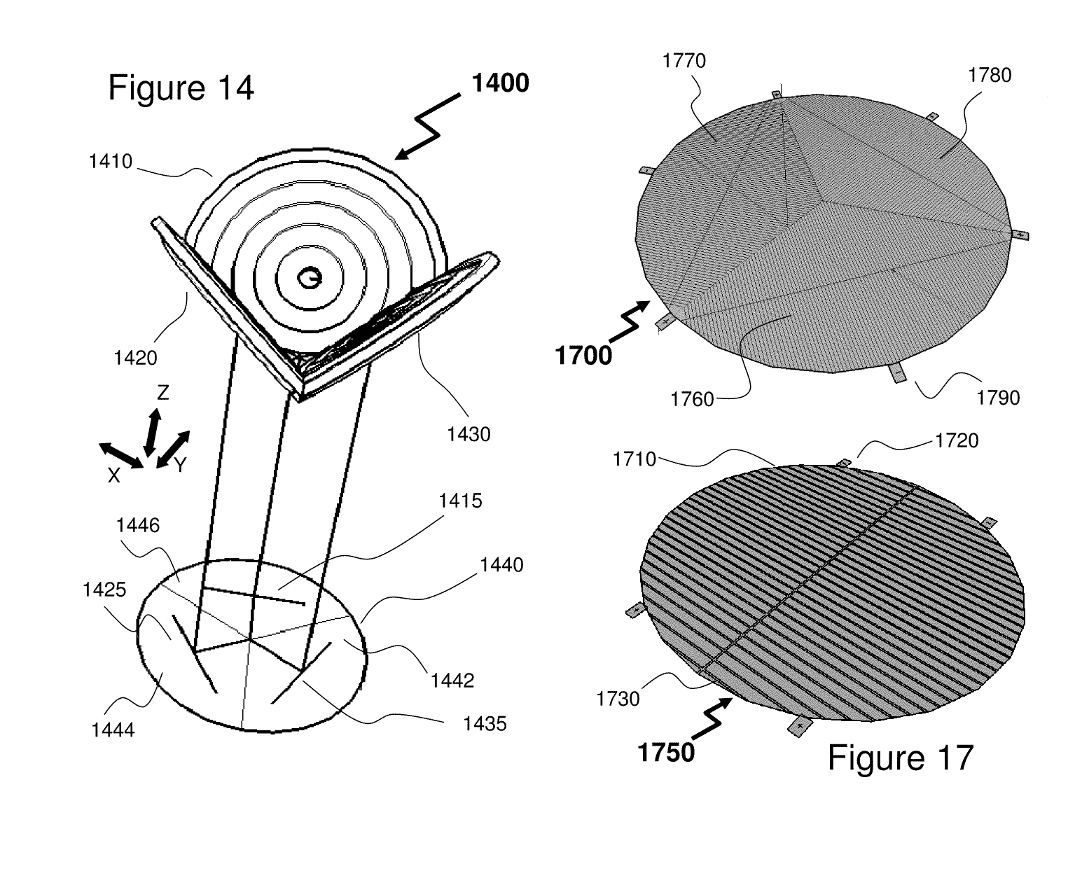

Now referring to FIG. 14 there is depicted a triple concentrator lens 1400 according to an embodiment of the invention. As shown triple concentrator lens 1400 comprises three lens elements 1410, 1420 and 1430 that each forms a surface of a fructo-pyramid and concentrate incoming solar radiation onto segments 1442, 1444 and 1446 of PV cell 1440. Each of the three lens elements 1410, 1420, and 1430 respectively being positioned such that their axes along the surface of the fructo-pyramid align with projected axes 1415, 1425 and 1435 respectively as shown in FIG. 14. It would be apparent to one skilled in the art that each of the three lens elements 1410, 1420 and 1430 are orientated at angles with respect to the X-Y plane of the PV cell 1440 as taught by the embodiments of the invention described within FIGS. 6 to 15 and FIGS. 17 to 18 respectively.

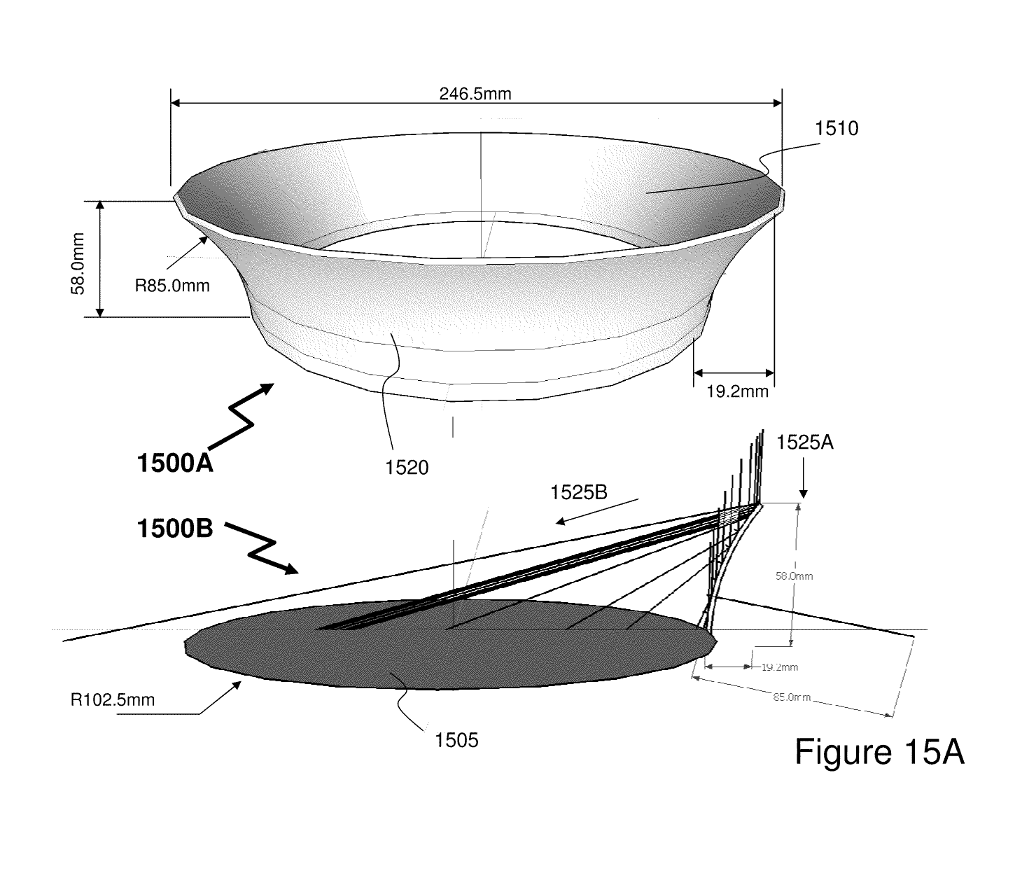

As discussed supra in respect of FIGS. 8 and 9 supra placement of a reflective assembly, such as outlined below in respect of reflective baffles 1500A and 1550A in FIGS. 15A and 15B respectively, positioned at a fixed angle outside the diameter of the solar panel will reflect solar radiation impinging upon it across the full surface area of the PV cell thereby capturing solar radiation concentrated outside the PV cell during periods of time that the azimuth-altitude assembly has not moved the solar power generator since as described supra the controller “jogs” the assembly in a non-continuous manner For example rotation may be set as large as 2 minutes of rotation and adjustment for yearly rotation may be set to increments between 2 days and 15 days. As such the reflective assembly provides for efficient solar energy generation with periodic re-alignment of the solar power generator.

Referring initially to FIG. 15A there is depicted a reflective baffle 1500A according to an embodiment of the invention forming the second element in the optical train of a solar power generator. Reflective baffle 1500A being for example employed as reflector 925 in FIG. 9 or reflector 860 in FIG. 8. As shown reflective baffle 1500A consists of a thin walled predetermined portion of a fructo-conical shape having a convex internal surface 1510 and an outer surface 1520 of radius 85 mm such that the surface of reflective baffle 1500A offsets by 19.2 mm over it's 58 mm height. The reflective baffle 1500A having an outer diameter at the top nearest the concentrator lens of 246.5 mm. As shown in FIG. 9 the reflector 925 is attached to solar assembly frame 915 below lens 920 such that solar radiation being concentrated by lens 920 and off-axis is reflected by the inner surface 1510 as shown in FIG. 15B with ray diagram 1500B. As shown a cross-section of one side of the reflective baffle 1500A is shown together a 205 mm diameter PV cell 1505 wherein the upper surface of PV cell 1505 and lower surface of reflective baffle 1500A are on the same horizontal plane. Also shown are incoming rays 1525A, which are impinging on the inner surface of the reflective baffle 1500A, e.g. convex internal surface 1510, and become reflected rays 1525B which then couple to PV cell 1505.

Now referring FIG. 15B there is depicted a reflective baffle 1550A according to an embodiment of the invention forming the second element in the optical train of a solar power generator. Reflective baffle 1550A being for example employed as reflector 925 in FIG. 9 or reflector 860 in FIG. 8. As shown reflective baffle 1550A consists of a thin walled predetermined portion of a fructo-conical shape having a convex internal surface 130 and an outer surface 1540 of radius 80 mm such that the surface of reflective baffle 1550A offsets by 17.5 mm over it's 57.6 mm height. The reflective baffle 1550A having an outer diameter at the top nearest the concentrator lens of 244.3 mm. As shown in FIG. 9 the reflector 925 is attached to solar assembly frame 915 below lens 920 such that solar radiation being concentrated by lens 920 and off-axis is reflected by the inner surface 1530 as shown in FIG. 15B with ray diagram 1550B. As shown a cross-section of one side of the reflective baffle 1550A is shown together a 205 mm diameter PV cell 1505 wherein the upper surface of PV cell 1505 and lower surface of reflective baffle 1500A are on the same horizontal plane. Also shown are incoming rays 1545A, which are impinging on the inner surface of the reflective baffle 1550A, e.g. convex internal surface 1530, and become reflected rays 1545B which then couple to PV cell 1505.

Referring to FIG. 16 there are depicted two optical assemblies 1600 and 1650 representing the placement of PV cells 1610 and 1660 respectively at two separations from a concentrator lens 1620. Concentrator lens 1620 being of the same design as concentrator lens 1320 in FIG. 13 supra being a 150 mm diameter lens. As such in first optical assembly 1600 the separation between concentrator lens 1620 and PV cell 1610 is 440 mm such that whilst the optical beam is being concentrated it has not been done substantially at this separation such that thermal management limits are not exceeded wherein the optical assembly 1600 is used as part of a solar generator such as solar generator 800 of FIG. 8 in a geographical location with high ground solar energy such as equatorial regions of Africa, the Americas, and Australia. As such PV cell 1610 is of a diameter approximately 100 mm, such as a 4″ (100 mm) silicon PV cell. In second optical assembly 1650 the separation between concentrator lens 1620 and PV cell 1610 is increased to 840 mm wherein increased concentration occurs such that a small PV cell 1660 is employed, being approximately 40 mm in diameter. As such small PV cell 1660 may for example exploit more expensive GaAs or InGaAsP technologies which have higher efficiency such that the solar power generator employing second optical assembly 1650 in lower ground solar energy regions such as eastern seaboard of United States, Canada, Europe, Russia etc can extract similar electrical output power.

As such it would be apparent to one of skill in the art that the solar power generators according to embodiments of the invention may be designed in some embodiments as a single design with a common concentrator lens wherein the separation from concentrator lens 1620 to the PV cell is established based upon the deployment location of the solar power generator and the selection of the PV cell which therefore establishes the thermal limits of the assembly. As such first and second optical assemblies 1600 and 1650 may be two settings for a single solar power generator wherein in one country, e.g. Kenya, the unit is sold with low cost silicon PV cell element(s) whereas in Norway the unit is sold with more expensive GaAs PV cell element(s) to increase electricity output despite the reduced ground solar energy. As such a common solar power generator can be implemented in some embodiments of the invention to leverage high volume manufacturing cost reductions.

Referring now to FIG. 17 there are depicted two PV cell designs according to embodiments of the invention for use within solar power generators such as solar power generator 900 in FIG. 9. First PV cell 1700 consists of first and second semi-circular PV elements 1710 and 1730 respectively and which are mounted to the solar assembly, such as base plate 930, by mounts 1720. Second PV cell 1750 consists of first, second, and third PV elements 1760, 1770 and 1780 and is similarly mounted to the solar assembly by mounts 1790.

First and second PV cells 1700 and 1750 are shown as circular in overall outline but comprised of two or three sections respectively which are semi-circular and fan shapes respectively. It would be apparent that the implementation of the PV cells may achieved using different configurations ranging from discrete single element PV cells formed from large silicon wafers or multiple elements electrically interconnected. Such multiple elements within the prior art including for example shingling elements, see for example C. Z Leinkram in U.S. Pat. No. 3,769,091 entitled “Shingled Array of Solar Cells” and L. M. Fraas in US Patent Application 2003/0,201,007 entitled “Planar Solar Concentrator Power Module”. Such configurations aiming to minimize regions of the assemblies that do not generate electricity and connect the array of PV cell elements to achieve the desired output voltage. Within first PV cell 1700 the cell elements within are connected in series to achieve the desired voltage output for each application. First semi-circular PV element 1710 being connected to provide an output with a positive terminal and the second semi-circular PV element 1720 being connected to provide a negative terminal. Within second PV cell 1750 the three fan sections, being first, second, and third PV elements 1760, 1770 and 1780, are shown for example oriented in parallel in one direction and positioned in a circular pattern. Tabbing wire 1785 is seen on each fan shape section to interconnect for example one set of terminals.

Referring to FIG. 18 there is depicted a solar power generator 1800 according to an embodiment of the invention employing three optical trains. As shown solar power generator 1800 comprises a post 1810 which has attached lower housing 1820. Mounted to the top of post 1810 is mounting 1830 which supports the solar assembly and allows rotation to track the daily motion of the sun. For example mounting 1830 may be a ball bearing mount to allow low friction rotation of the upper assembly whilst driven by gear 1845 on the lower frame 1840 through control of gear drive controller 1860. Lower frame 1840 then supports altitude frame 1835 which adjusts the altitude of the solar assembly to provide adjustment for inclination of the sun during the year. Gear drive controller 1860 would be programmed according to the location of the solar power generator 1800.

Mounted upon altitude frame 1835 would be a solar assembly frame but this has been omitted for clarity. Attached to the solar assembly frame, not shown, are three base plates, also not shown for clarity, upon each of which are disposed PV cells 1870A, 1870B and 1870C respectively. Disposed adjacent to each of the PV cells 1870A, 1870B and 1870C respectively are reflectors 1880A, 1880B and 1880C respectively, such as described supra in respect of FIG. 14. Also disposed axially with respect to a vertical projected perpendicularly from the centre of each PV cell 1870A, 1870B and 1870C respectively are lenses 1890A, 1890B and 1890C. Accordingly solar power generator 1800 employs three concentrator lenses, being lenses 1890A, 1890B and 1890C coupling solar radiation to three PV cells 1870A, 1870B and 1870C respectively.

If each optical train within solar power generator 1800 exploits a 300 mm diameter lens of a design comparable to any of first through third lenses 1220 to 1240 in FIG. 12 then these would be placed approximately 250 mm in front of each PV cell. As a result solar power generator 1800 would be enclosed and protected with cover, not shown for clarity but for example comprising upper external body 730 and lid 740 as shown in FIG. 7, and have a dimension of approximately 700 mm (28 inches) in diameter and 860 mm (34 inches) high. It would be apparent that according to the design of the mechanical assembly and solar assemblies that 1, 2, 3, 4 or more solar assemblies may be mounted to a single mechanical assembly. As such solar power generator 1800 may be implemented to provide different electrical output powers. Placement of the lenses would for example be based upon hexagonal packing to minimize the dimensions of the solar power generator. Additionally it would be evident that solar generator 1800 and other implementations according to embodiments of the invention may be disposed in locations other than on the side facing of buildings, roof tops etc. Further units may be deployed discretely or in multiples according to the requirements of the user and their space requirements.

It would be apparent that solar power generators 900 and 1800 each provide for an increase in electrical output power per unit area of the PV cells when compared to non-concentrated planar PV cells. The increase being by a filling factor ℑ as determined in Equation 1 below. Beneficially the solar power generators as taught by virtue of their azimuth-altitude tracking track the sun so that the solar cells present the fullest aspect with respect to the PV cells such that electricity output during a day is increased with respect to fixed planar PV panels.

$$𝒥 = η \frac{{A}_{LENS}}{{A}_{PV}} \qquad ( 1 )$$

where η is related to efficiency including factors such as transmittance of lens.

Within the above embodiments no active heat management in respect of the PV cells has been provided. It would be apparent to one skilled in the art that an exhaust fan or other suitable management system may be incorporated into solar power generators according to embodiments of the invention to prevent the internal temperature exceeding a predetermined threshold determined by either the optical train, the mechanical systems such as azimuth-altitude adjustment, or the electronics within the controller. For the PV cells only passive heat sinking is provided. It would be apparent that active heat sink management techniques may be applied to solar power generators according to embodiments of the invention to increase the filling factor ℑ, for example where expensive higher efficiency PV cells such as GaAs or InGaAsP are employed.

It would be apparent that adjusting the dimensions of the lens, number of lenses per housing, etc may be varied. Outlined below are some examples of deployments according to embodiments of the invention. It would also be apparent that in many applications low concentration ratios, [symbol] =Area_{Lens}/Area_{PV}, may also be employed within solar power generators as the azimuth-altitude tracking in conjunction with the reflecting baffle increase overall output power during morning/evening and from fall through to spring.

Exemplary Scenario 1: For outdoor or indoor applications employing three 250 mm (10″) diameter lens assemblies in conjunction with three 200 mm (8″) diameter P|V cells with for example second lens 1230 or third lens 1240. The lenses would be offset at between 20 degrees and 40 degrees and at between 200 mm to 450 mm away with respect to the plane of the PV cells. Within this configuration the reflective baffle for each solar assembly would be placed at an inclination of between 15 degrees and 40 degrees outward with respect to an axis perpendicular to its respective PV cell.

Exemplary Scenario 2: For outdoor or indoor applications employing a three ring 300 mm (12″) diameter lens in conjunction with a 200 mm diameter PV cell made from three fan sections would be installed with a separation of 300 mm between lens and PV cell and with an angular offset of approximately 30 degrees. Each solar panel section is rated at 5 watts conventional power. The power will be increased by 3 to 4 times by refraction when the angle between the surfaces of the lens/panel is about 30 degrees. Within this configuration the reflective baffle for each solar assembly would be placed at an inclination of between 15 degrees and 40 degrees outward with respect to an axis perpendicular to its respective PV cell.

Exemplary Scenario 3: A single 150 mm (6″) diameter lens in conjunction with a 40 mm diameter PV cell with lens-cell separation of 840 mm between lens and panel. Employing a plano concave/convex lens such as first lens 1220 with the lens diameter, PV cell, separation, allowed the central concave section of the 8 mm lens, such as concave surface 1215A to be calculated. The angle between the lens surface and the PV cell is rotated to about 0 degrees (in parallel) with the reflective baffle being set at an angle of about 20 degrees with respect to the perpendicular from the PV cell.

Exemplary Scenario 4: For indoor applications a small model employing a 50 mm (2″) PV cell in conjunction with a 125 mm (5″) concave-convex lens such as third lens 1240 orientated at an angle of approximately 30 degrees from plane parallel to the PV cell and the reflective baffle orientated at approximately 20 degrees from the axis perpendicular to the PV cell.

Exemplary Scenario 5: For compact apparatus a double concave-double convex lens such as second lens 1230 is used to reduce the distance required between the solar panel and the lens by about 50% in comparison to using a plano concave-convex lens such as first lens 1220. A separation of approximately 200 mm was employed between the 150 mm (6″) diameter lens and 40 mm diameter PV cell the lens orientated at an angle of approximately 30 degrees from plane parallel to the PV cell and the reflective baffle orientated at approximately 20 degrees from the axis perpendicular to the PV cell.

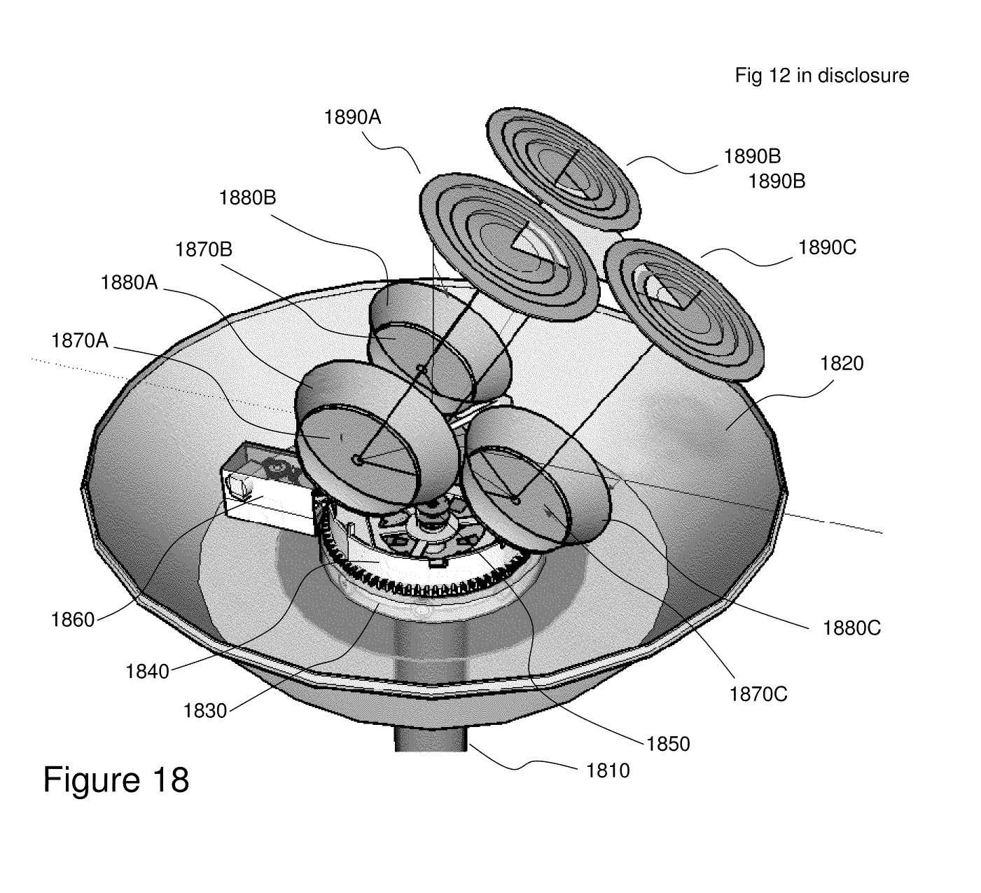

Experimental Results: In the embodiments of the invention presented supra in respect of FIGS. 7 through 18 a variety of configurations have been described for the concentrating lens, reflector and PV cell. Common to all has been the absence of thermal management for the PV cell which would add cost and complexity to the solar power generator. The experimental results outlined below were achieved using a concentrator lenses of 150 mm and 170 mm diameter, the 170 mm lens design being shown by quarter concentrator lens section 1900 in FIG. 19 and referred to subsequently as concave convex lens. Lens section 1900 showing the lens as having radius 85.0 mm, central thickness 5 mm in lower half which is reflected into upper half for a total lens thickness of 10 mm at the centre which increases to a thickness of 8 mm (i.e. 16 mm total lens thickness at 49.5 mm radius, is planar for 5 mm and then curves away over the final 30.5 mm to zero.

Result A: With a tilted concave convex lens and a PV cell separation of 490 mm the short circuit current from the PV cell was 320 mA, and 80 mA without the lens at 2.0V-2.3V.

Result B: With a tilted plano concave convex lens such as described supra in respect of FIG. 12A at 490 mm from a 2.0V PV cell in conjunction with flat reflective mirrors yielded short circuit current of 430 mA compared to 80 mA under same sun conditions without cooling.

Result C: Tilted concave convex lens and PV cell with separation at 880 mm and tilt angle of approximately 56 degrees with 2.0V PV cell yielded a short-circuit current of 360 mA compared to 80 mA without. Subsequent measurements on the same day with reduced sun yielded 230 mA with the tilted lens and 40 mA without.

Result D: A tilted concave convex lens as per result A indoors behind a dusty window in March 2009 in Toronto, Canada yielded 58 mA versus 15 mA without the lens with a separation of 320 mA.

Result E: The same configuration as with result D but with increased separation of 640 mA yielded 58 mA again versus 15 mA.

Result F: Tilted concave convex lens at approximately 57 degrees with dusty basement window and separation 270 mm yielded 104 mA versus 35 mA without the lens.

Result G: Tilted concave convex lens with 490 mm separation yielded 90 mA behind windshield of inventor's car when compared to 22 mA without the lens.

Result H: Tilted concave convex lens through window on foggy sunny day, Feb. 25, 2009 yielded 36.9 mA with a 250 mm separation. Without the lens the short circuit current was 9.8 mA.

Result I: Tilted concave convex lens with four element PV cell wherein middle pair of cells are blocked by shadow of sun without the lens yielding 1.8 mA. Addition of the lens increasing current to 39 mA.

Result J: A tilted concave convex lens at 490 mm with 15 degree tilt behind dusty window indoors yielded 75 mA compared to 18.3 mA without the lens.

Result K: Tilted plano concave convex lens at separation of 470 mm and tilt of 15 degrees yielded 130 mA compared to 40 mA when PV cell connected to a battery charging circuit

It would be apparent to one skilled in the art that solar power generators according to embodiments of the invention provide for reduced installation costs as the generators are designed for post mounting and hence may be deployed without requiring physical infra-structures be present. Where the generators are not post mounted but are attached to physical infra-structure the reduced physical footprint of the generators according to embodiments of the invention allow increased flexibility in their placement.

Within the above embodiments the controller and adjustment of the solar power generator have been discussed in respect of a chronological control. It would be apparent to one of skill in the art that the control may alternatively be based upon other measures including for example the measurement of the solar radiation and a differential measurement of the solar radiation. Optionally the controller may be chronological with a measurement indicative of the solar radiation.

The above-described embodiments of the present invention are intended to be examples only. Alterations, modifications and variations may be effected to the particular embodiments by those of skill in the art without departing from the scope of the invention, which is defined solely by the claims appended hereto.

What is claimed is:

1. A device comprising:
a cell responsive to radiation within a predetermined first wavelength range and characterized by at least first and second dimensions along axes perpendicular to one another in a plane parallel to a surface of the cell; and
a lens transmissive to a predetermined second wavelength range that overlaps a predetermined portion of the predetermined first wavelength range and focusing radiation within the predetermined first wavelength range, the lens characterized by at least third and fourth dimensions along the same axes as the first and second dimensions respectively wherein at least one of the third dimension and fourth dimension is larger than the corresponding first dimension and second dimension, wherein in operation the lens has a predetermined separation from the cell and the plane of the lens is offset by a predetermined non-zero angle with respect to said plane of the cell.

2. A device according to claim 1 further comprising;
a reflector comprising at least an inner surface and an outer surface and having a first end disposed towards the cell and a distal end disposed towards the lens, the first end having a geometry determined in dependence upon at least the geometry of the cell and the inner surface being reflective to radiation within the predetermined first wavelength range, wherein in operation an axis of the reflector along which the first end and distal end are disposed is offset at a predetermined angle with respect to an axis between a centre of the lens and a centre of the cell.

3. A device according to claim 1 wherein,
the cell and lens form part of an assembly that under direction of a controller moves according to at least one of a measure of time and a measure of solar radiation.

4. A device according to claim 1 wherein,
the cell is absent at least one of active temperature stabilization and active temperature management.

5. A device according to claim 1 wherein,
the predetermined non-zero angle is between 10 degrees and 60 degrees.

6. A device comprising:
a base for at least one of mounting the device to a structure and insertion into the ground;
a mount mounted upon the base and comprising at least a frame and an altitude mechanism, the altitude mechanism for adjusting the elevation of the frame with respect to the base;
a controller for controlling at least the altitude mechanism and an azimuth mechanism, the azimuth mechanism for adjusting the rotational position of the frame with respect to the base;
a cell attached to the frame and responsive to radiation within a predetermined first wavelength range and characterized by at least first and second dimensions along axes perpendicular to one another in a plane of parallel to a surface of the cell; and
a lens attached to the frame and transmissive to a predetermined second wavelength range that overlaps a predetermined portion of the predetermined first wavelength range and focusing radiation within the predetermined first wavelength range, the lens characterized by at least third and fourth dimensions along the same axes as the first and second dimensions respectively wherein at least one of the third dimension and fourth dimension is larger than the corresponding first dimension and second dimension, wherein in operation the lens has a predetermined separation from the cell and the plane of the lens is offset by a predetermined non-zero angle with respect to said plane of the cell.

7. A device according to claim 6 further comprising;
a reflector comprising at least an inner surface and an outer surface and having a first end disposed towards the cell and a distal end disposed towards the lens, the first end having a geometry determined in dependence upon at least the geometry of the cell and the inner surface being reflective to radiation within the predetermined first wavelength range, wherein in operation an axis of the reflector along which the first end and distal end are disposed is offset at a predetermined angle with respect to an axis between a centre of the lens and a centre of the cell.

8. A device according to claim 6 wherein,
the cell and lens form part of an assembly that under direction of a controller moves according to at least one of a measure of time and a measure of solar radiation.

9. A device according to claim 6 wherein,
the cell is absent at least one of active temperature stabilization and active temperature management.

10. A device according to claim 6 wherein,
the predetermined non-zero angle is between 10 degrees and 60 degrees.

11. A device according to claim 6 further comprising;
a cover enclosing a predetermined region around the device, a predetermined portion of the cover manufactured from a material transmissive to radiation within the predetermined portion of the predetermined first wavelength range.

12. A device comprising:
a base for at least one of mounting the device to a structure and insertion into the ground;
a mount mounted upon the base and comprising at least a frame and an altitude mechanism for adjusting the elevation of the frame with respect to the base;
a controller for controlling at least the altitude mechanism and an azimuth mechanism for adjusting the rotational position of the frame with respect to the base;
a cell attached to the frame and responsive to radiation within a predetermined first wavelength range and characterized by at least first and second dimensions along axes perpendicular to one another in a plane of parallel to a surface of the cell;
a lens attached to the frame and transmissive to a predetermined second wavelength range that overlaps a predetermined portion of the predetermined first wavelength range and focusing radiation within the predetermined first wavelength range, the lens characterized by at least third and fourth dimensions along the same axes as the first and second dimensions respectively wherein at least one of the third dimension and fourth dimension is larger than the corresponding first dimension and second dimension, wherein in operation the lens has a predetermined separation from the cell and the plane of the lens is offset by a predetermined angle with respect to said plane of the cell; and
a reflector comprising at least an inner surface and an outer surface and having a first end disposed towards the cell and a distal end disposed towards the lens, the first end having a geometry determined in dependence upon at least the geometry of the cell and the inner surface being reflective to radiation within the predetermined first wavelength range, wherein in operation an axis of the reflector along which the first end and distal end are disposed is offset at a predetermined non-zero angle with respect to an axis between a centre of the lens and a centre of the cell.

13. A device according to claim 12 wherein,
the cell and lens form part of an assembly that under direction of a controller moves according to at least one of a measure of time and a measure of solar radiation.

14. A device according to claim 12 wherein,
the cell is absent at least one of active temperature stabilization and active temperature management.

15. A device according to claim 12 wherein,
the predetermined non-zero angle is between 10 degrees and 60 degrees.

16. A device according to claim 12 further comprising;
a cover enclosing a predetermined region around the device, a predetermined portion of the cover manufactured from a material transmissive to radiation within the predetermined portion of the predetermined first wavelength range.
